(19) United States
(12) Patent Application Publication
(10) Pub. No.: US 2016/0259243 A1
(43) Pub. Date: Sep. 8, 2016

(54) NEGATIVE-WORKING LITHOGRAPHIC PRINTING PLATE PRECURSOR

(71) Applicant: Eastman Kodak Company, Rochester, NY (US)

(72) Inventors: Eiji Hayakawa, Utsunomiya-shi (JP); Masamichi Kamiya, Oura-gun (JP); Yoshiaki Shekiguchi, Kumagaya-shi (JP); Koji Hayashi, Tatebayashi-shi (JP)

(21) Appl. No.: 14/636,240

(22) Filed: Mar. 3, 2015

(51) Int. Cl. G03F 7/027; B41C 1/10; G03F 7/038

(52) U.S. Cl. CPC G03F 7/027; G03F 7/038; B41C 1/10

(57) ABSTRACT

A negative-working lithographic printing plate precursor has a substrate and an imageable layer disposed on the substrate. This imageable is removable with a lithographic printing ink, a fountain solution, or both. The imageable layer comprises (A) a free radical polymerizable compound, (B) a free radical polymerization initiator, and (C) a polymer that has a polysaccharide backbone and a free radical polymerizable group that is different than (A). Such precursors are on-press developable and exhibit excellent on-press development stability over time and excellent printing properties.

### FIELD OF THE INVENTION

The present invention relates to negative-working lithographic-printing plate precursors that can be used to provide lithographic printing plates using on-press development. More particularly, the present invention relates to an infrared-sensitive or heat-sensitive negative-working lithographic printing plate precursors that can be used as a computer-to-plate (CTP) plate capable of directly recording images by irradiation with infrared radiation from a solid or semiconductor laser corresponding to digital signals.

### BACKGROUND OF THE INVENTION

With the progress of computer image processing techniques, a method of directly recording images on a photosensitive layer by irradiation corresponding to digital signals has recently been developed, and thus there has been intense interest in a computer-to-plate (CTP) system in which images are directly formed on a negative-working lithographic printing plate precursor, without using a silver salt mask film, by employing the method using a negative-working lithographic printing plate precursor. The CTP system, which uses a high-output laser having a maximum intensity within the near infrared or infrared range as a light source for the irradiation, has the following advantages: images having high resolution can be obtained by exposure within a short time and the negative-working lithographic printing plate precursor used in the system can be handled in daylight. Regarding solid and semiconductor lasers capable of emitting infrared rays having a wavelength of 760 nm to 1,200 nm, high-output and portable lasers are readily available.

Negative-working lithographic printing plate precursors that can be used to form images with using a solid state or semiconductor laser are generally known in the art. It is also known that some of such precursors can be imagewise exposed and then developed on-press, and thus do not need any conventional developing process after a light exposure process. Non-exposed parts of the imageable layers in the precursors can be removed using a fountain solution and or lithographic printing ink, or both while the imaged precursor is on the printing press.

Known on-press developable negative-working lithographic printing plate precursors may not require any waste treatment process which is necessary in a conventional developing process, and therefore have fewer effects on the environment.

However, further improvements are needed to improve on-press development stability over time and printing properties.

### SUMMARY OF THE INVENTION

The present invention addresses the problems noted above. In particular, the present invention provides a negative-working lithographic printing plate precursor, comprising:

a substrate and an imageable layer disposed on the substrate,

wherein:

the imageable layer is removable by a lithographic printing ink, a fountain solution, or both a lithographic printing ink and fountain solution, and

the imageable layer comprises:
(A) at least one free radical polymerizable compound,
(B) at least one free radical polymerization initiator, and
(C) at least one polymer that has a polysaccharide backbone having a free radical polymerizable group and that is different from (A).

In some embodiments, the polysaccharide in (C) is cellulose or a derivative thereof. Moreover, the free radical polymerizable group in (C) can be bonded to the polysaccharide backbone via either at least one urethane bond, at least one urea bond, or both a urethane bond and a urea bond.

Moreover, in some embodiment, (C) is derived from, at least, a polysaccharide, a polyisocyanate, and either an alcohol other than a polysaccharide or an amine, or both an alcohol other than a polysaccharide and an amine. For example, the alcohol other than a polysaccharide or amine can have a free radical polymerizable group.

In still other embodiments, (C) can have at least one poly(alkyleneoxide) moiety. For example, the free radical polymerizable group can be linked to the polysaccharide backbone via a spacer comprising the poly(alkyleneoxide) moiety.

In the practice of the present invention, it is useful that (C) be present in the imageable layer in an amount of at least 1% and up to and including 50% by mass, based on the total mass of the imageable layer.

Moreover, It is preferable that the ingredient (A) have at least one poly(alkyleneoxide) moiety.

As described below in more detail, (A) be a multi-functional urethane acrylate. Also, (B) can comprise a heat-polymerization initiator, or the imageable layer further comprises (E) a photo-thermal conversion material. Moreover, the imageable layer can further comprise (D) that is at least one particulate polymer binder other than the (C) polymer.

The present invention provides negative-working lithographic printing plate precursors that are on-press developable and that exhibit excellent on-press development stability over time and excellent printing properties.

The present invention also provides a method for preparing a lithographic printing plate from a negative-working lithographic printing plate described herein, this method comprising at least on-press developing the noted precursor. The method can also comprise: imagewise exposing the negative-working lithographic printing plate precursor to provide an imagewise exposed precursor; mounting the imagewise exposed precursor onto a printing press to provide a mounted precursor; and on-press developing the mounted precursor by contacting it with either a lithographic printing ink, a fountain solution, or both a lithographic printing ink and a fountain solution, in this noted order.

Alternatively, the method can comprise: mounting the negative-working lithographic printing plate precursor onto a printing press; imagewise exposing the negative-working lithographic printing plate precursor to provide an imagewise exposed precursor; and on-press developing the imagewise exposed precursor by contacting it with either a lithographic printing ink, a fountain solution, or both a lithographic printing ink and fountain solution, in this noted order.

The negative-working lithographic printing plate precursor according to the present invention is on-press developable, and exhibits excellent on-press development stability over time and excellent printing properties. In particular, the precursor can be rapidly developed on-press, and the resulting lithographic printing plate obtained according to the present invention exhibits good ink receptivity, can be preserved for a long period of time, and can exhibit a long printing press life.

It is possible to form images on the negative-working lithographic printing plate precursor according to the present invention using solid state or semiconductor laser exposure.

The negative-working lithographic printing plate precursor of the present invention does not need any normal off-press developing process, and therefore its use does not generate any waste developer that must be processed in waste-treatment processes. Accordingly, it is possible to prepare a lithographic printing plate in a relatively short period of time with a negative-working lithographic printing plate precursor according to the present invention, and to control the impact on the environment caused by the preparation (making up) of the lithographic printing plate.

### DETAILED DESCRIPTION OF THE INVENTION

### Substrate

Any substrate can be used in the negative-working lithographic printing plate precursor as long as it has properties, such as strength, durability and flexibility, which are necessary for use in lithographic printing plates.

As the substrate, mention may be made of sheets of aluminum, zinc, copper, stainless steel, and iron; plastic films made of polyethylene terephthalate, polycarbonate, polyvinyl acetal, polyethylene, etc.; composite materials obtained by forming a metal layer on papers which are melt-coated with a synthetic resin or coated with a synthetic resin solution, plastic films and the like, using technologies such as vacuum deposition and laminating; and a material used as the substrate of the lithographic printing plate. A substrate made of aluminum or a composite substrate in which a substrate made from material(s) other than aluminum is coated with aluminum, is particularly useful.

The surface of the aluminum substrate can be surface-treated for the purpose of enhancing water retentivity and improving adhesion with an imageable layer or an optionally formed intermediate layer. Examples of the surface treatment include roughening treatments such as a brush graining method, a ball graining method, electrolytic etching, chemical etching, liquid honing, and sandblasting, and a combination thereof. Among these, a roughening treatment including use of electrolytic etching is particularly useful.

As an electrolytic bath in the case of electrolytic etching, for example, an aqueous solution or an aqueous solution containing an organic solvent can be used, the organic solvent containing an acid, an alkali or a salt thereof. Among these, an electrolytic solution containing hydrochloric acid, nitric acid, or a salt thereof is useful.

Furthermore, the aluminum substrate can be subjected to the roughening treatment and a desmutting treatment using an aqueous solution of an acid or an alkali, if necessary. The aluminum substrate thus obtained can be subjected to an anodic oxidation treatment, for example, using a bath containing sulfuric acid or phosphoric acid. Furthermore, it is also useful to perform, after the anodic oxidation treatment, a pore-widening treatment in which the size of the micropores in the coating prepared by the anodic oxidation treatment is enlarged, by contacting the coating with an acid or alkaline aqueous solution. In each case, the coating can be treated such that the pore size or pore diameter of the micropores on the coating is in the range of at least 5 nm and up to and including 100 nm. The pore size for sulfuric acid anodization is typically less than 20 nm, whereas the pore size for phosphoric acid anodization is typically 20 nm or more. It may be useful for the anodized substrate to have pores with a size of 20 nm or more, for example 20 to 100 nm, on the surface thereof.

It is also useful to use an aluminum substrate that has been subjected to a hydrophilization treatment, after the roughening treatment (graining treatment) and the anodic oxidation treatment. As the hydrophilization treatment, mention can be made of, a sealing treatment by immersing an aluminum substrate in a hot aqueous solution containing hot water and an inorganic salt or an organic salt, or performed using a steam bath; a silicate treatment (for example, sodium silicate, potassium silicate); a potassium fluorozirconate treatment; a phosphomolybdate treatment; an alkyl titanate treatment; a polyacrylic acid treatment; a polyvinylsulfonic acid treatment; a polyvinylphosphonic acid treatment; a phytic acid treatment; a treatment with a hydrophilic organic polymer compound and a divalent metal salt; a hydrophilization treatment by undercoating with a water soluble polymer having a sulfonic acid group, a carboxylic acid group, an amide group, or two or more thereof; a coloring treatment with an acidic dye; electrodeposition with a silicate; and a treatment with a mixed solution of a fluorine compound and a phosphate compound as described in, for example, paragraph [0048], and in particular paragraph [0055], of JP-A-2011-215476. It is useful for the surface of the substrate to have an underlayer comprising at least one water-soluble polymer such as polyacrylic acid.

### Imageable Layer

The negative-working lithographic printing plate precursor according to the present invention comprises at least one negative-working imageable layer. If necessary, it can comprise a plurality of imageable layers. A negative-working imageable layer can be referred to as a negative-working photosensitive layer or just photosensitive layer. The negative-working lithographic printing plate precursor according to the present invention comprises at least a negative-working imageable layer in which image-wise exposed portions thereof are cured or hardened to form imaging portions. The imageable layer is of the thermal negative-working type, in which irradiated portions with an IR-laser are cured or hardened to form imaged regions.

The imageable layer in the negative-working lithographic printing plate precursor can be prepared from a composition comprising (A) at least one free radical polymerizable compound, (B) at least one free radical polymerization initiator, and (C) at least one polymer which has a polysaccharide backbone having a free radical polymerizable group and that is different from (A). Thus, the imageable layer comprises at least the above components (A) to (C) as essential components.

(A) Free Radical Polymerizable Compound:

The (A) free radical polymerizable compound is a compound that is capable of free radical polymerization. Such component can be a single compound or a combination of a plurality of compounds.

The free radical polymerizable compound is not specifically limited, but it can be a compound having one or more addition-polymerizable ethylenically unsaturated bonds. The compound can be optionally selected from compounds having at least one, and possibly two or more ethylenically unsaturated double bond groups. The compound has chemical forms, for example, monomer and prepolymer such as dimer, trimer and oligomer, or mixtures thereof and copolymers thereof. Examples of the monomer and the copolymer thereof include but are not limited to an ester of an unsaturated carboxylic acid (for example, acrylic acid, methacrylic acid, itaconic acid, crotonic acid, isocrotonic acid, and maleic acid) and an aliphatic polyhydric alcohol compound, and an amide of an unsaturated carboxylic acid and an aliphatic polyhydric amine compound.

Specific examples of the ester of the aliphatic polyhydric alcohol compound and the carboxylic acid include acrylate esters such as ethylene glycol diacrylate, triethylene glycol diacrylate, 1,3-butanediol diacrylate, tetramethylene glycol diacrylate, propyleneglycol diacrylate, neopentyl glycol diacrylate, trimethylolpropane triacrylate, trimethylolpropanetri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol pentaacrylate, dipentaerythrito hexaacrylate, sorbitol triacrylate, sorbitol tetraacrylate, sorbitol pentaacrylate, sorbitol hexaacrylate, tri(acroyloxyethyl) isocyanurate, and a polyester acrylate oligomer.

Examples of methacrylate esters include tetramethylene glycol dimethacrylate, triethylene glycol dimethacrylate, neopentylglycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, dipentaerythritol pentamethacrylate, sorbitol trimethacrylate, sorbitol tetramethacrylate, bis[p-(3-methacryloxy-2-hydroxypropoxy)phenyl]dimethylmethane, and bis-[p-(methacryloxyethoxy)phenyl]dimethylmethane.

Examples of itaconate esters include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of crotonate esters include ethylene glycol dicrotonate, tetramethylene glycol dicrotonate, pentaerythritol dicrotonate, and sorbitol tetradicrotonate.

Examples of isocrotonate esters include ethylene glycol diisocrotonate, pentaerythritol diisocrotonate, and sorbitol tetraisocrotonate.

Examples of maleate esters include ethylene glycol dimaleate, triethylene glycol dimaleate, pentaerythritol dimaleate, and sorbitol tetramaleate. Furthermore, mixtures of the above ester monomers can be utilized.

Specific examples of the amide of the aliphatic polyvalent amine compound and the unsaturated carboxylic acid include methylenebis-acrylamide, methylenebis-methacrylamide, 1,6-hexamethylenebis-acrylamide, 1,6-hexamethylenebis-methacrylamide, diethylenetriaminetrisacrylamide, xylylenebisacrylamide, and xylylenebismethacrylamide.

As a specific free radical polymerizable compound, mention is made of Sartomer SR399 marketed by Sartomer Company, having the following structure.

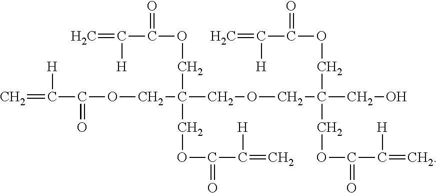 [SMILES: C=CC(=O)OCC(CO)(COCC(COC(=O)C=C)(COC(=O)C=C)COC(=O)C=C)COC(=O)C=C]

Sartomer SR494 marketed by Sartomer Company, having the following structure;

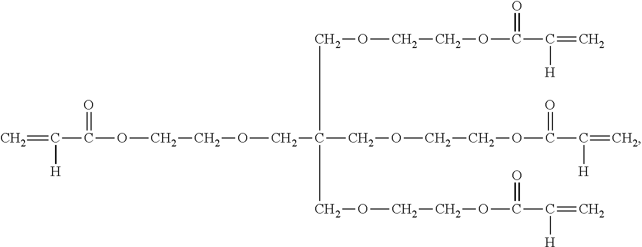 [SMILES: C=CC(=O)OCCOCC(COCCOC(=O)C=C)(COCCOC(=O)C=C)COCCOC(=O)C=C]

trimethylolpropaneethoxylate triacrylate, and others like them.

The (A) free radical polymerizable compound can have at least one poly(alkyleneoxide) moiety.

As the alkyleneoxide, alkylene oxide with 2-6 carbon atoms is preferable, and ethylene oxide, propylene oxide, tetramethylene oxide, or hexamethylene oxide are useful. As the repeating number of alkylene oxides in the poly(alkyleneoxide) moiety, 1 to 50 is useful and typically 1 to 20.

The poly(alkyleneoxide) moiety can have a structure represented by the following general formula (1):

—COO—[(CH₂)ₓ(CH(R¹))O]_{y}— (1)

or the general formula (2):

—COO—[(CH(R¹))(CH₂)ₓO]_{y}— (2)

wherein,
x is an integer from 1 to 5,
y is an integer from 1 to 400, and
R¹ independently denotes a hydrogen atom or an alkyl group,
or
the following general formula (3):

—COO—[(CH₂)_{z}(CH(R²))O]ₘ—[(CH₂)ₙ(CH((R³))O]_{q}— (3)

or the following general formula (4):

—COO—[(CH(R²))(CH₂)_{z}O]ₘ—[(CH(R³))(CH₂)ₙO]_{q}— (4)

wherein:
each of n and z is independently an integer of at least 1 and up to and including 5,
each of m and q is independently an integer of at least 1 and up to and including 200, and
R² and R³ independently denote a hydrogen atom or an alkyl group, provided that R² and R³ are different if n and z are the same number.

In the general formulae (1), (2), (3) and (4) shown above, y, m, and q can be an integer of at least 1 and up to and including 50, or typically of at least 1 and up to and including 20; R¹, R² and R³ can be a hydrogen atom or a methyl group.

As the (A) free radical polymerizable compound with a poly(alkyleneoxide) moiety or moieties, an ester of an unsaturated carboxylic acid (for example, acrylic acid, methacrylic acid, itaconic acid, crotonic acid, isocrotonic acid, maleic acid, etc.) and an aliphatic polyhydric alcohol compound with a poly(alkyleneoxide) moiety or moieties at the ester portion(s) are useful.

As a suitable (A) free radical polymerizable compound with poly(alkyleneoxide) moieties, mention may be made of Sartomer SR602 marketed by Sartomer Company having the following structure.

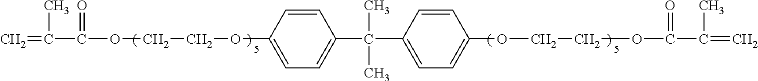

Other examples include a vinylurethane compound having two or more polymerizable vinyl groups in a molecule, which is obtained by adding the ester of the unsaturated carboxylic acid and the aliphatic polyhydric alcohol compound, or a vinyl monomer having a hydroxyl group represented by the following general formula (A) or (B) to a polyisocyanate compound having two or more isocyanate groups in a molecule such as hexamethylene diisocyanate. The compound to be reacted with an isocyanate group can have an amino group and an imino group in the molecule.

CH₂═C(Q¹)COOCH₂CH(Q²)OH (A)

wherein Q¹ and Q² independently represent H or CH₃.

(CH₂═C(Q¹)COOCH₂)ₐC(Q²)_{b}(Q³)_{c} (B)

wherein Q¹ and Q² independently represent H or CH₃, Q³ represents —CH₂OH, and a and c each independently represents an integer of 1 to 3 and b represents an integer of 0 or 1 or 2, provided that a+b+c is 4.

Mention can also be made of polyfunctional acrylates and methacrylates, for example, the urethane acrylates described in JP-A-S51-37193, the polyester acrylates described in JP-A-S48-64183, JP-B-S49-43191 and JP-B-S52-30490, and epoxy acrylates obtained by reacting an epoxy resin with (meth)acrylic acid. Furthermore, the photocurable monomers and oligomers described in the Journal of Japanese Adhesion Society, Vol. 20, No. 7, pp. 300-308 (1984) can be used.

Specific examples thereof include NK OLIGO U-4HA, U-4H, U-6HA, U-15HA, U-108A, U-1084A, U-200AX, U-122A, U-340A, U-324A, US-53H and UA-100 (manufactured by Shin-Nakamura Chemical Co., Ltd.); UA-306H, AI-600, UA-101T, UA-101I, UA-306T and UA-306I (manufactured by Kyoeisha Oil and Fats Chemical Ind. Co., Ltd.); ART RESIN UN-9200A, UN-3320HA, UN-3320HB, UN-3320HC, UN-3320HS, SH-380QG SH-500, SH-9832, UN-901T, UN-904, UN-905, UN-906, UN-906S, UN-907, UN-952, UN-953, UN-954, H-91 and H-135 (manufactured by Negami Chemical Industrial Co., Ltd.); and Sartomer CN968, CN975, CN989, CN9001, CN9010, CN9025, CN9029, CN9165 and CN2260 (manufactured by Sartomer Company).

The (A) free radical polymerizable compound can be a multi-functional urethane acrylate, such as a multi-functional urethane acrylate with a functionality of 5 or more, or a multi-functional urethane acrylate with a functionality of 10 or more.

It is useful that the multi-functional urethane acrylate have a molecular weight of 1000 or more, or 1500 or more, and even 2000 or more. The molecular weight is based on the number-average molecular weight.

As a suitable multi-functional urethane acrylate, mention can be made of a polymerizable compound obtained by reacting Desmodur N100 (aliphatic polyisocyanate resin including hexamethylene diacrylates marketed by Bayer) with hydroxyethylacrylate(s) and pentaerythritoltriacrylate(s).

The (A) free radical polymerizable compound can be present in the imageable layer or the composition for preparing the imageable layer in an amount within the range of at least 10% and up to and including 90% by mass (weight), or at least 20% and up to and including 80% by mass, and more likely of at least 30% and up to and including 70% by mass, based on the solid content of the imageable layer or the composition used for preparing the imageable layer.

(B) Free Radical Polymerization Initiator:

The (B) free radical polymerization initiator forms a radical or radicals to initiate the polymerization of the free radical polymerizable compound(s). The (B) free radical polymerization initiator may be a single compound or a combination or system of a plurality of compounds.

Heat-Polymerization Initiator and Photo-Polymerization Initiators:

It is useful that the (B) free radical polymerization initiator comprise at least one heat-polymerization initiator or at least one photo-polymerization initiator, or both.

As a heat-polymerization initiator or a photo-polymerization initiator, it is possible to use various heat-polymerization initiators and photo-polymerization initiators known from various publications alone or in combination (heat-polymerization initiation system or photo-polymerization initiation system) after appropriate selection according to temperature or the wavelength of a light source to be used. In the present invention, the heat-polymerization initiator(s) or the photo-polymerization initiator(s) to be used alone or in combination are merely referred to as a “heat-polymerization initiator” or “photo-polymerization initiator”.

As the heat-polymerization initiator, organic borate compounds, onium salts and mixtures thereof are useful. These heat-polymerization initiators may be used alone or in combination.

An organic borate compound can exhibit a function as a polymerization initiator by using it in combination with the photo-thermal converting material explained below. The organic borate compound can be an ammonium salt of a quaternary borate anion, which is represented by the following formula (5):

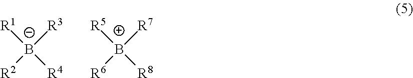

wherein R¹, R², R³ and R⁴ each independently represents an alkyl group, an aryl group, an alkaryl group, an allyl group, aralkyl group, an alkenyl group, an alkynyl group, an alicyclic group, or a saturated or unsaturated heterocyclic group, and R⁵, R⁶, R⁷ and R⁸ each independently represents a hydrogen atom, an alkyl group, an aryl group, an allyl group, an alkaryl group, an aralkyl group, an alkenyl group, an alkynyl group, an alicyclic group, or a saturated or unsaturated heterocyclic group.

Among these, tetra n-butylammonium n-butyltriphenylborate, tetra n-butylammonium n-butyl trinaphthylborate, tetra n-butylammonium n-butyltri(p-t-butylphenyl)borate, tetramethylammonium n-butyltriphenylborate, tetramethylammonium n-butyltrinaphthylborate, tetramethylammonium n-octyltriphenylborate, tetramethylammonium n-octyltrinaphthylborate, tetraethylammonium n-butyltriphenylborate, tetraethylammonium n-butyltrinaphthylborate, trimethylhydrogenammonium n-butyltriphenylborate, triethylhydrogenammonium n-butyltriphenylborate, tetrahydrogenammonium n-butyltriphenylborate, tetramethylammonium tetra n-butylborate, tetraethylammonium tetra n-butylborate, tetraethylammonium tetraphenylborate, tetraethylammonium tetrakis(pentafluorophenyl)borate and the like can be used because a polymerization function is efficiently exhibited.

The organic borate compound can exhibit a function as a polymerization initiator by using it in combination with the photo-thermal converting material (for example, D⁺) in the case of generating a radical (R⁻), for example, by irradiation with infrared rays, as shown in the following scheme (6):

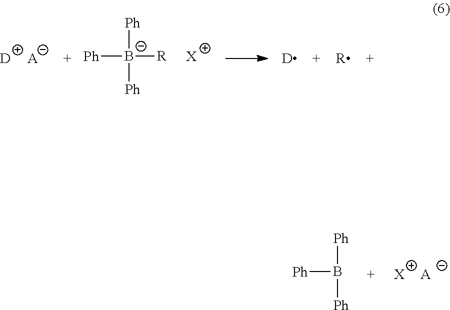

wherein Ph represents a phenyl group or a phenyl group in which at least one hydrogen atom is replaced with at least one fluorine atom, R represents a phenyl group, a phenyl group in which at least one hydrogen atom is replaced with at least one fluorine atom, or an alkyl group having 1 to 8 carbon atoms, and X⁺ represents an ammonium ion.

The content of the organic borate compound can be within the range of at least 0.1% and up to and including 15% by mass, and particularly at least 0.5% and up to and including 7% by mass, based on the solid content of the imageable layer. If the content of the organic borate compound is less than 0.1% by mass, an insufficient polymerization reaction may lead to poor curing and the resulting photosensitive lithographic printing plate may have a weak image area. On the other hand, if the content of the organic borate compound is more than 15% by mass, the polymerization reaction may not efficiently occur. If necessary, at least two organic borate compounds can be used in combination.

It is particular useful that the heat-polymerization initiator is an onium salt. An onium salt is a salt comprising a cation having at least one onium ion atom in the molecule, and an anion. Examples of the onium ion atom in the onium salt include S⁺ atom in sulfonium, I⁺ atom in iodonium, N⁺ atom in ammonium, P⁺ atom in phosphonium, and N₂⁺ atom in diazonium. Among these onium ion atoms, S⁺, I⁺ and N₂⁺ atoms are particularly useful. Examples of the structure of the onium salt include triphenylsulfonium, diphenyliodonium, diphenyldiazonium, and derivatives obtained by introducing an alkyl group, an aryl group, an alkoxy group, a halogen atom or the like into the benzene ring of these compounds, and derivatives obtained by introducing an alkyl group and an aryl group into the benzene ring of these compounds.

Examples of the anion of the onium salt include halogen anion, ClO₄⁻, PF₆⁻, BF₄⁻, SbF₆⁻, CH₃SO₃⁻, CF₃SO₃⁻, C₆H₅SO₃⁻, CH₃C₆H₄SO₃⁻, HOC₆H₄SO₃⁻, ClC₆H₄SO₃⁻, and borate anion represented by the above formula (5).

The onium salt can be obtained by combining an onium salt having S⁺ in the molecule with an onium salt having f in the molecule in view of sensitivity and storage stability. In view of sensitivity and storage stability, the onium salt can be a polyvalent onium salt having at least two onium ion atoms in the molecule. At least two onium ion atoms in the cation are bonded through a covalent bond. Among polyvalent onium salts, those having at least two onium ion atoms in the molecule are useful and those having St and I⁺ in the molecule are particularly useful. Particularly useful polyvalent onium salts are represented by the following formulas (7) and (8):

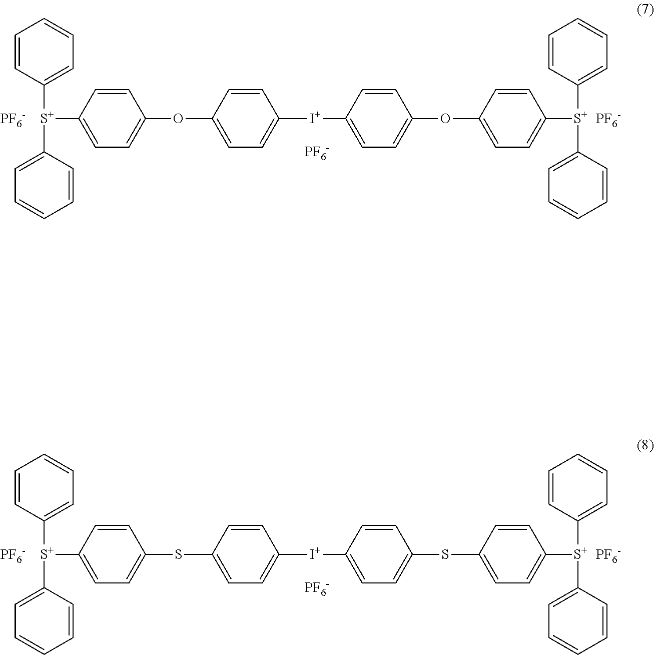

Furthermore, the onium salts described in paragraphs [0033] to [0038] of the specification of JP-A-2002-082429 or the iodonium borate complexes described in paragraphs [0037] to [0049] of the specification of JP-T-2009-538446 (cf. page 9, line 3 to page 12, line 23 of WO 2007/139687) can also be used in the present invention.

According to an embodiment of the present invention, the photo-thermal converting material as explained below absorbs infrared radiation (IR) and converts the absorbed IR to heat. An onium salt can be decomposed by the heat generated thereby to form radicals. Due to the formed radicals, the chain polymerization of the free radical polymerizable compound(s) proceeds to cure or harden the exposure portions of the imageable layer.

The content of the onium salt can be within the range of at least 0.1% and up to and including 25% by mass, and typically at least 1.0% and up to and including 15% by mass, based on the solid content of the imageable layer or the composition used for preparing the imageable layer. If the content of the onium salt is less than 0.1% by mass, the resulting negative-working photosensitive lithographic printing plate precursor may be insufficient with respect to sensitivity and resulting printing plate printing durability because of insufficient polymerization reaction. On the other hand, if the content of the onium salt is more than 25% by mass, the resulting exposed precursor may be inferior with respect to the developing properties. If necessary, at least two onium salts can be used in combination. Also a polyvalent onium salt may be used in combination with a monovalent onium salt.

As the photo-polymerization initiator, triazine-based compound(s) are useful, alone or in combination.

The triazine-based compound is a known polymerization initiator that is used in free radical polymerization. For example, bis(trihalomethyl)-s-triazine can be used as the photo-polymerization initiator.

The amount of the triazine-based compound is usually a small amount. If the amount is too large, this may lead to unsatisfactory results because the triazine-based compound causes a reduction in sensitivity and is crystallized and reprecipitated in the photosensitive imageable layer after coating. The content of the triazine-based compound is generally at least 0.1% and up to and including 15% by mass based on the solid content of the imageable layer or the composition used for preparing the imageable layer. If the amount is at least 0.5% and up to and including 7% by mass, good results can be obtained.

To the photo-polymerization initiator, optional accelerators, for example, a mercapto compound such as mercapto-3-triazole, and an amine compound, can be added.

If a polymerization initiator other than the organic boron compounds, onium salts and triazine-based compounds is used, the polymerization initiator can be present in the imageable layer or the composition for preparing the imageable layer in an amount of at least 0.001% and up to and including 20% by mass, or at least 0.01 and up to and including 10% by mass, and more likely at least 0.1% and up to and including 5% by mass, based on the solid content of the imageable layer or the composition used for preparing the imageable layer.

Photo-Thermal Converting Materials:

It is useful that the imageable layer, in particular, the free radical polymerization initiator included in the imageable layer, comprise at least one (E) photo-thermal converting material. The photo-thermal converting material refers to any material capable of converting electromagnetic waves into thermal energy and is a material having a maximum absorption wavelength within the near infrared or infrared range, for example, a material having a maximum absorption wavelength within the range of at least 760 nm and up to and including 1,200 nm. Examples of such a substance include various pigments and dyes.

The pigments useful in the present invention are commercially available pigments described, for example, in “Color Index Handbook”, “Latest Pigment Handbook” (edited by Nihon Pigment Technique Society, published in 1977), “Latest Pigment Application Technique” (published by CMC in 1986), and “Printing Ink Technique” (published by CMC in 1984). Applicable types of pigments include black, yellow, orange, brown, red, violet, blue and green pigments, fluorescent pigments and polymer-grafted dyes. For example, the following can be used: insoluble azo pigments, azo lake pigments, condensed azo pigments, chelated azo pigments, phthalocyanine pigments, anthraquinone pigments, perylene and perinone pigments, thiomindigo pigments, guinacridone pigments, dioxazine pigments, isoindolinone pigments, quinophthalone pigments, lake pigments, azine pigments, nitroso pigments, nitro pigments, natural pigments, fluorescent pigments, inorganic pigments, and carbon black.

Among these pigments, carbon black is useful as a material that efficiently absorbs light in the near infrared or infrared range and is also economically superior. As the carbon black, grafted carbon blacks having various functional groups that are excellent in dispersibility and commercially available are preferable, and examples thereof include those described on page 167 of “The Carbon Black, Handbook, 3rd edition” (edited by the Carbon Black Society of Japan and issued in 1995) and those described on page 111 of “Characteristics, Optimum Blending and Applied Technique of Carbon Black” (edited by Technical Information Society in 1997).

These pigments can be used without surface treatment, or used after being subjected to a surface treatment. As a method of surface treatment, mention is made of a method of surface-coating a resin or a wax, a method of attaching a surfactant, and a method of binding a reactive substance (e.g. silane coupling agent, epoxy compound, or polyisocyanate) to the surface of a pigment. The above-mentioned surface treatment methods are described in “Property and Application of Metal Soap” (Saiwai Shobou), “Printing Ink Technique” (published by CMC in 1984) and “Latest Pigment Application Technique” (published by CMC in 1986). The particle size of these pigments is generally at least 0.01 μm and up to and including 15 μm, and more likely at least 0.01 μm and up to and including 5 μm.

The dyes useful in the present invention are conventionally known commercially available dyes described, for example, in “Dye Handbook” (edited by the Association of Organic Synthesis Chemistry, published in 1970), “Handbook of Color Material Engineering” (edited by the Japan Society of Color Material, Asakura Shoten K. K., published in 1989), “Technologies and Markets of Industrial Dyes” (published by CMC in 1983), and “Chemical Handbook, Applied Chemistry Edition” (edited by The Chemical Society of Japan, Maruzen Shoten K. K., published in 1986). Specific examples of the dyes include azo dyes, azo dyes in the form of metal complex salts, pyrazolone azo dyes, anthraquinone dyes, phthalocyanine dyes, carbonium dyes, quinonimine dyes, methine dyes, cyanine dyes, indigo dyes, quinoline dyes, nitro-based dyes, xanthene-based dyes, thiazine-based dyes, azine dyes, and oxazine dyes.

As the dyes capable of efficiently absorbing near infrared rays or infrared rays, for example, the following dyes can be used: azo dyes, metal complex azo dyes, pyrazolone azo dyes, naphthoquinone dyes, anthraquinone dyes, phthalocyanine dyes, carbonium dyes, quinoneimine dyes, methine dyes, cyanine dyes, squalirium dyes, pyrylium salts and metal thiolate complexes (for example, nickel thioate complexes). Among these, cyanine dyes are preferable, and examples thereof are the cyanine dyes represented by the general formula (I) of JP-A-2001-305722 and the compounds described in paragraphs [0096] to [0103] of JP-A-2002-079772.

In particular, as the dyes, a near infrared radiation absorbing cationic dye represented by the formula shown below is useful since it enables a heat-polymerization initiator to efficiently exert a polymerization function:

D⁺A⁻

wherein
D⁺ represents a cationic dye absorbing in the near infrared range, and
A⁻ represents an anion.

Examples of the cationic dye absorbing in the near infrared range include a cyanine-based dye, a triarylmethane-based dye, an aminium-based dye and a diimmonium-based dye, each absorbing in the near infrared range. Specific examples of a cationic dye absorbing in the near infrared range include those shown below.

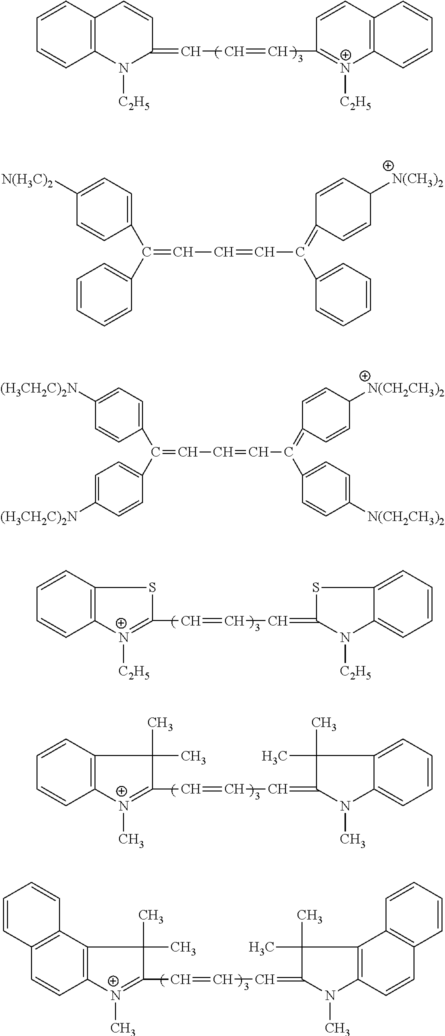

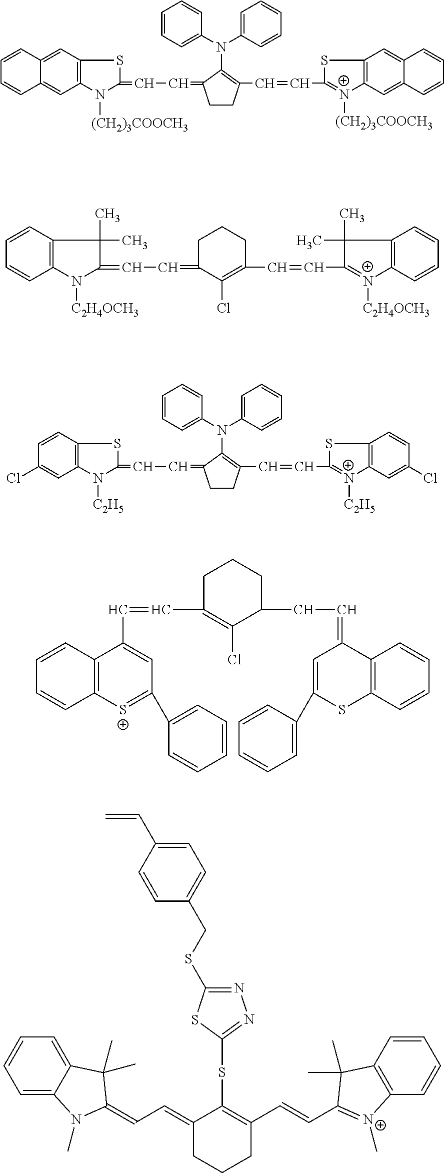

Examples of the anion include a halogen anion, ClO₄⁻, PF₆⁻, BF₄⁻, SbF₆⁻, CH₃SO₃⁻, CF₃SO₃⁻, C₆H₅SO₃⁻, CH₃C₆H₄SO₃⁻, HOC₆H₄SO₃⁻, ClO₆H₄SO₃⁻, and a borate anion represented by the following formula (9). The borate anion can be a triphenyl n-butyl borate anion, a trinaphthyl n-butyl borate anion, or a tetraphenyl borate anion.

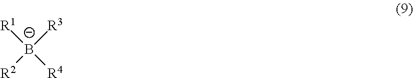

wherein
R¹, R², R³ and R⁴ independently denote an alkyl group, an aryl group, an aralkyl group, an alkenyl group, an alkynyl group, an alicyclic group, or a saturated or unsaturated heterocyclic group.

As the photo-thermal converting material, the cyanine dye represented by the following chemical formula is useful.

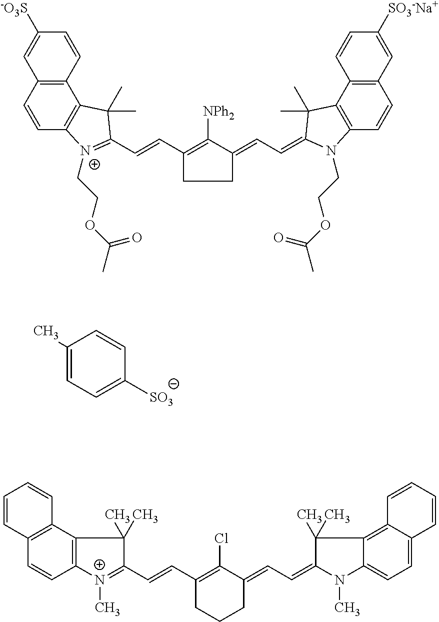

As other preferable cyanine dyes, mention may be made of the compounds listed in paragraphs [0017] to [0019] of JP-A-2001-133969, paragraphs [0016] to [0021] of JP-A-2002-023360, paragraphs [0012] to [0037] of JP-A-2002-040638, preferably the compounds listed in paragraphs [0034] to [0041] of JP-A-2002-278057, paragraphs [0080] to [0086] of JP-A-2008-195018, and most preferably the compounds listed in paragraphs [0035] to [0043] of JP-A-2007-090850. Also, the compounds listed in paragraphs [0008] to [0009] of JP-A-H05-005005 and paragraphs [0022] to [0025] of JP-A-2001-222101 can be used.

The photo-thermal converting material can be present in the imageable layer or the composition for preparing the imageable layer in an amount in an amount of at least 0.001 and up to and including 20% by mass, or at least 0.01% and up to and including 10% by mass, and more typically at least 0.1% and up to and including 5% by mass, based on the solid content of the imageable layer or the composition used for preparing the imageable layer. If the amount is less than 0.001% by mass, imaging sensitivity may decrease. On the other hand, if the amount is more than 20% by mass, the non-imaged regions can be contaminated during printing. These photo-thermal converting materials can be used alone or in combination.

(C) Polymer:

The (C) polymer included in the imageable layer of the negative-working lithographic printing plate precursor according to the present invention has a polysaccharide backbone (main chain) having at least one free radical polymerizable group. Since the (C) polymer has the free radical polymerizable group(s), the (C) polymer is a compound that is free radically polymerizable. The (C) polymer can be a single compound or a combination or system of a plurality of compounds. The (C) polymer is different from the (A) free radical polymerizable compound. Thus, the (A) and (C) components are not the same compound.

The polysaccharide that forms the polysaccharide backbone of the (C) polymer is not particularly limited, and can be a polymer of two or more monosaccharide molecules joined by a glycoside bond or bonds. As the polysaccharide, a polymer of monosaccharides each of which has 4 or more, or even 5 or more, and typically 6 or more hydroxyl groups, can be used. The polysaccharide can also be a derivative. The main chain or backbone of the (C) polymer is constituted by a polysaccharide. It is useful that the (C) polymer has no polysaccharide in the compound side chains.

As the polysaccharide or the derivative thereof, mention may be made of, for example, cellulose guar gum, starch, hydroxyethyl cellulose, hydroxyethyl guar gum, hydroxyethyl starch, methyl cellulose, methyl guar gum, methyl starch, ethyl cellulose, ethyl guar gum, ethyl starch, hydroxypropyl cellulose, hydroxypropyl guar gum, hydroxypropyl starch, hydroxyethylmethyl cellulose, hydroxyethylmethyl guar gum, hydroxyethylmethyl starch, hydroxypropylmethyl cellulose, hydroxypropylmethyl guar gum, hydroxypropylmethyl starch, and others known in the art.

As the polysaccharide or the derivative thereof, cellulose or a derivative thereof is useful such as cellulose, hydroxyethyl cellulose, methyl cellulose, ethyl cellulose. The substituent(s), such as a methyl group, an ethyl group, a hydroxyethyl group and a hydroxypropyl group, of these polysaccharides can be of a single type or of different type(s). The substitution degree per constituting monosaccharide thereof can be at least 0.1 and up to and including 10, or typically at least 0.5 and up to and including 5. The weight average molecular weight of the polysaccharide or the derivative thereof can be at least 5,000 and up to and including 10,000,000, or at least 8,000 and up to and including 5,000,000, and even at least 10,000 and up to and including 1,000,000.

It is useful that the free radical polymerizable group in the (C) polymer is linked to the polysaccharide backbone via either at least one urethane bond or at least one urea bond, or both a urethane bond and a urea bond. A polymerizable group can be linked to the (C) polymer via, for example, 1 to 5, or 1 to 3, and even 1 or 2, urethane bond(s); or 1 to 5, or 1 to 3, and even 1 or 2, urea bond(s); or both 1 to 5, or 1 to 3, and even 1 or 2, urethane bond(s) and 1 to 5, or 1 to 3, and even 1 or 2, urea bond(s).

Thus, in some embodiments, the (C) polymer can be derived from, at least, a polysaccharide, a polyisocyanate, and either an alcohol other than a polysaccharide or an amine, or both an alcohol other than a polysaccharide and an amine. In other words, it is possible that the (C) polymer is obtained by the reaction of, at least, a polysaccharide, a polyisocyanate, and either an alcohol other than a polysaccharide or an amine, or both. A urethane bond can be formed by the reaction with the isocyanate group of the polyisocyanate and the hydroxyl group of the polysaccharide or the alcohol. A urea bond can be formed by the reaction with the isocyanate group of the polyisocyanate and the amino group of the amine.

The polyisocyanates can have a plurality of isocyanate groups, and cover diisocyanates having two isocyanate groups and polyisocyanates having three or more isocyanate groups in a molecule.

The diisocyanates are not particularly limited as long as they have two isocyanate groups. Mention is made of, for example, 4,4′-diphenylmethanediisocyanate, xylylenediisocyanate, naphthylene-1,5-diisocyanate, tetramethylxylene-diisocyanate, hexamethylenediisocyanate, toluene-2,4-diisocyanate, toluene-2,6-diisocyanate, isophoronediisocyanate, hydrogenated xylylenediisocyanate, dicyclohexylmethanediisocyanate, norbornenediisocyanate, trimethylhexamethylenediisocyanate, dimer acid diisocyanate, and others known in the art.

The polyisocyanates are not particularly limited as long as they have three isocyanate groups. Mention is made of, for example, triphenylmethane-4,4,4-triisocyanate and the like; compounds obtained by reacting a compound having three or more hydroxyl groups in a molecule, such as glycerin, pentaerythritol and polyglycerin, with a diisocyanate compound such as hexamethylenediisocyanate, toluenediisocyanate, isophoronediisocyanate and trimethylhexamethylenediisocyanate; a compound obtained by reacting a compound having two or more hydroxyl groups in a molecule such as ethyleneglycol, with a compound having three or more isocyanate groups in a molecule, e.g., a biuret-type compound such as Duranate 24A-100, 22A-75PX, 21 S-75E, and 18H-70B marketed by Asahi Kasei Corporation; and an adduct-type compound such as Duranate P-301-75E, E-402-90T, E-405-80T marketed by Asahi Kasei Corporation.

The alcohol compound other than a polysaccharide has at least one hydroxyl group, and covers a monoalcohol having one hydroxyl group in a molecule, a diol having two hydroxyl groups in a molecule and a polyol having 3 or more hydroxyl groups in a molecule.

As the monoalcohol having one hydroxyl group, mention is made of, for example, an ethylene-type unsaturated compound having a hydroxyl group. It is useful that the ethylene-type unsaturated compound has at least one non-aromatic C—C double bond that can be a terminal group. It is useful that the hydroxyl group not be linked to the carbon atom that is double bonded, and that it is not a part of a carboxyl group. It is useful that the ethylene-type unsaturated compound has no further functional group, such as an imino group, that can react with an isocyanate, in addition to the hydroxyl group.

Examples of the ethylene-type unsaturated compound include hydroxyl(C₁-C₁₂)alkyl (meth)acrylates (for example, 2-hydroxylethyl(meth)acrylate, 2- or 3-hydroxypropyl(meth)acrylate, 2-, 3- or 4-hydroxybutyl(meth)acrylate); hydroxyl(C₁-C₁₂)alkyl(meth)acrylamides (for example, 2-hydroxyethyl(meth)acrylamide, 2- or 3-hydroxypropyl(meth)acrylamide, 2-, 3- or 4-hydroxybutyl(meth)acrylamide); mono(meth)acrylate of oligomer or polymer of ethyleneglycol or propyleneglycol (for example, polyethyleneglycol mono(meth)acrylate and triethyleneglycol mono(meth)acrylate); allylalcohol; 4-hydroxy(C₁-C₁₂)alkylstyrenes (for example, 4-hydroxymethylstyrene); 4-hydroxystyrene; and hydroxycyclohexyl(meth)acrylates.

Furthermore, as examples of the ethylene-type unsaturated compound, mention is made of a compound having at least one alcoholic hydroxyl group which is obtained by an esterification reaction of a compound having a plurality of alcoholic hydroxyl groups and a compound including a carboxyl group and a (meth)acryloyl group, i.e., a product obtained by the reaction with the carboxyl group-containing compound in a proportion such that at least one alcoholic hydroxyl group can remain. Specifically, a hydroxyl group-containing polyfunctional acrylate compound having at least one alcoholic hydroxyl group which is an ester of a polyhydric alcohol and acrylic acid, such as a compound obtained by reacting 3 moles of acrylic acid and 1 mole of pentaerythritol, 2 moles of acrylic acid and 1 mole of pentaerythritol, 5 moles of acrylic acid and 1 mole of dipentaerythritol, or 4 moles of acrylic acid and 1 mole of dipentaerythritol. As specific compounds, mention may be made of pentaerythritol triacrylate, pentaerythritol diacrylate, dipentaerythritol diacrylate, dipentaerythritol triacrylate, dipentaerythritol tetraacrylate, dipentaerythritol pentaacrylate and others known in the art.

The diols are not particularly limited as long as they have two hydroxyl groups. Mention is made of dimethylolpropane, polypropyleneglycols, neopentylglycols, 1,3-propanediol, polytetramethyleneetherglycols, polyesterpolyols, polymerpolyols, polycaprolactonepolyols, polycarbonatediols, 1,4-butanediol, 1,5-pentanediol, 3-methyl-1,5-pentanediol, 1,6-hexanediol, polybutadienepolyols, and 1,4-dihydroxymethylbenzene.

As the polyols having three or more hydroxyl groups, mention is made of: glycerin; sugar alcohols such as erythritol, xylitol, mannitol, sorbitol and xylitol; pentaerythritol; dipentaerythritol; and others known in the art.

The amine has at least one amino group, and covers diamines having two amino groups in a molecule, and polyamines having three or more amino groups in a molecule.

Diamines are not particularly limited as long as they have two amino groups. Mention is made of polyoxyalkylenediamine, 3,3-diaminodiphenylsulfone, norbornanediamine, 2,4-diamino-6-hydroxypyrimidine, 1,3-diaminopropane, p-xylenediamine, m-phenylenediamine, p-phenylenediamine, 4,4′-diaminodiphenylpropane, 4,4′-diaminodiphenylmethane, 4,4′-diaminodiphenylether, 4,4′-diaminodiphenylsulfone, 3,3′-dimethyl-4,4′-diaminodiphenylmethane, 1,5-diaminonaphthalene, 1,4-diaminoanthraquinone, 2,6-diaminoanthraquinone, 2,6-diaminopyridine, 4,6-diamino-2-mercaptopyrimidine, 1,6-diaminohexane and others known in the art.

As polyamines having three or more amino groups, mention is made of, for example, polyoxyalkylenetriamine, 2,4,6-triaminopyrimidine, polyamine resin (polyvinylamine polymers, polyallylamine polymers, polydiallylamine resin, amino(meth)acrylate polymers).

In the present invention, it is desirable that the above alcohol or the above amine have the free radical polymerizable group.

As the alcohol having the free radical polymerizable group, mention is be made of, for example, the above ethylene-type unsaturated compound having a hydroxyl group.

As the amine having the free radical polymerizable group, mention is made of, for example, the above polyamine resin.

When the polysaccharide, the polyisocyanate, and either the alcohol other than a polysaccharide or the amine, or both, are reacted, it is desirable that, first, the polyisocyanate be reacted with the alcohol other than a polysaccharide or the amine, or both, to prepare a monoisocyanate compound, and that, second, the monoisocyanate compound obtained by the above reaction be further reacted with the polysaccharide.

It is desirable that the (C) polymer has hydroxyl group(s) or have no isocyanate group. Thus, it is desirable that the molar ratio of the hydroxyl groups of the polysaccharide:the isocyanate groups of the monoisocyanate compound (the half urethane compound and/or the half urea compound) be 5:1 to 1:1, or 3:1 to 1:1, and even 2:1 to 1:1.

The (C) polymer can be present in the imageable layer or the composition used for preparing the imageable layer in an amount of at least 1% and up to and including 50% by mass (weight), or at least 3% and up to and including 35% by mass, and even at least 5% and up to and including 20% by mass, based on the solid content of the imageable layer or the composition used for preparing the imageable layer.

(D) Polymer Binder:

The imageable layer of the negative-working lithographic printing plate precursor according to the present invention or the composition used for preparing the imageable layer can include (D) at least one particulate polymer binder different from the (C) polymer. It is desirable that the (D) particulate polymer binder has no free radical polymerizable groups.

The (D) polymer binder can be in the form of a polymer particle that has an average particle diameter of 50 nm or more, and also has one or more poly(alkyleneoxide) moieties. Two or more different particulate polymer particles can be present. Due to the polymer particle(s), the permeability of water and other aqueous solvents imageable layer is enhanced, and therefore, the on-press developability is enhanced.

The average particle diameter of the polymer particle is not limited as long as it is 50 nm or more, and can be at least 50 nm and up to and including 2000 nm, or at least 100 nm an up to and including 1500 nm, or even at least 150 nm and up to including 1200 nm.

The average particle diameter or size can be measured with a conventional measurement device based on a laser-diffraction or distribution principle. The term “average particle diameter” herein means a volume average particle diameter measured with a laser diffraction particle size analyzer.

In some embodiments, the alkyleneoxide moiety is a (C₁-C₆) alkylene oxide group, and is typically a (C₁-C₄) alkylene oxide group. For example, the alkylene oxide moiety or segment can include a linear or branched alkylene oxide group having 1 to 4 carbon atoms, such as —[CH₂O—], —[CH₂CH₂O—], —[CH(CH₃)O—], —[CH₂CH₂CH₂O—], —[CH(CH₃)CH₂O—], —[CH₂CH(CH₃)O—], —[CH₂CH₂CH₂CH₂O—], —[CH(CH₃)CH₂CH₂O—], —[CH₂CH(CH₃)CH₂O—], —[CH₂CH₂CH(CH₃)O-] or a substituted form thereof. In some embodiments, the poly(alkyleneoxide) moiety is composed of these constituent units. According to one embodiment, the poly(alkyleneoxide) moiety is composed of a —[CH₂CH₂—O-] constituent unit.

The poly(alkyleneoxide) unit typically includes in total of 1 to 200, or at least 2 to 150, and even at least 10 to 100 alkyleneoxide structural units. In general, the number average molecular weight (Mn) of the poly(alkyleneoxide) unit is at least 300 and up to and including 10,000, or at least 500 and up to and including 5,000, or even at least 1000 and up to and including 3,000.

For example, a useful pendant group including the poly(alkyleneoxide) moiety can have the following general formula (1):

—COO—[(CH₂)ₓ(CH(R¹))O]_{y}—R² (1)

or the general formula (2):

—COO—[(CH(R¹))(CH₂)ₓO]_{y}—R² (2)

wherein,
x is an integer from 1 to 5,
y is an integer from 1 to 400,
R¹ independently denotes a hydrogen atom or a methyl group, and
R² denotes a hydrogen atom or a monovalent hydrocarbon group having 1 to 8 carbon atoms,
or
the following general formula (3):

—COO—[(CH₂)_{z}(CH(R³))O]ₘ—[(CH₂)ₙ(CH(R⁴)O]_{q}—R⁵ (3)

or the following general formula (4):

—COO—[(CH(R³))(CH₂)_{z}O]ₘ—[(CH(R⁴))(CH₂)ₙO]_{q}—R⁵ (4)

wherein,
each of n and z is independently an integer from 1 to 5,
each of m and q is independently an integer from 1 to 200,
R³ and R⁴ independently denotes a hydrogen atom or a methyl group, provided that R³ and R⁴ are different if n and z are the same number, and
R⁵ denotes a hydrogen atom or a monovalent hydrocarbon group having 1 to 8 carbon atoms.

As the monovalent hydrocarbon group having 1 to 8 carbon atoms, mention is made of an alkyl group such as a methyl group, an ethyl group, a propyl group, a butyl group, a pentyl group, a hexyl group, a heptyl group, and an octyl group; a cycloalkyl group such as a cyclopentyl group and a cyclohexyl group; an alkenyl group such as a vinyl group, an allyl group and a butenyl group; an aryl group such as a phenyl group and tolyl group; an aralkyl group such as a benzyl group; and a group in which at least a part of the hydrogen atom(s) of the above group is/are substituted with a halogen atom such as a fluorine, or an organic group including an epoxy group, a glycidyl group, an acyl group, a carboxy group, an amino group, a methacryl group and a mercapto group, with the proviso that the total number of carbon atoms is 1 to 8.

A specific example of a suitable pendant group comprising the poly(alkyleneoxide) moiety has the following formula:

—C(—O)O—(CH₂CH₂O)_{y}—CH₃

wherein
y is from about 10 to about 100, and more preferably from about 25 to about 75. According to one embodiment, y is from about 40 to about 50.

The polymer can be characterized by a number average molecular weight (Mn) of at least 10,000 and up to and including 250,000, or at least 25,000 and up to and including 200,000.

The (D) particulate polymer can function as a binder and is generally a solid at room temperature and is typically a non-elastomeric thermoplastic. The polymer can comprise both hydrophilic and hydrophobic regions. Although not bound by any theory, the combination of hydrophilic and hydrophobic regions is thought to be important for enhancing differentiation of the exposed and non-exposed regions, to facilitate on-press developability.

The (D) particulate polymer may be an addition polymer or a condensation polymer. Addition polymers can be prepared from, for example, acrylate esters and methacrylate esters, acrylic and methacrylic acid, methyl methacrylate, allyl acrylate, and allyl methacrylate, acrylamides and methacrylamides, acrylonitrile and methacrylonitrile, styrene, hydroxystyrene or a combination thereof. Suitable condensation polymers include polyurethanes, epoxy resins, polyesters, polyamides and phenolic polymers, including phenol/formaldehyde, and pyrogallol/acetone polymers.

The (D) particulate polymer can include a hydrophobic main chain (backbone) including structural units having attached pendant groups. In some embodiments, the hydrophobic main chain is an all-carbon main chain, such as where the polymer is a copolymer derived from a combination of ethylenically unsaturated monomers. In other embodiments, the hydrophobic main chain may include heteroatoms, such as where the polymer is formed by a condensation reaction or some other means.

Specifically, it is desirable that the particulate polymer with two or more poly(alkyleneoxide) moieties be a polymer having a main chain that comprises no poly(alkyleneoxide) moiety, and two or more pendant groups comprising the two or more poly(alkyleneoxide) moieties. The phrase “comprises no poly(alkyleneoxide) moiety” means that no poly(alkyleneoxide) is present in the main chain. The main chain can be hydrophobic, and the pendant group can be hydrophilic.

For example, the polymer can be at least derived from at least two selected from the group consisting of poly(alkyleneglycol)alkylether(meth)acrylates and poly(alkyleneglycol)(meth)acrylates.

It is desirable that the polymer include a plurality of constitutional units having pendant cyano groups (—C≡N) attached directly to the hydrophobic main chain. By way of example only, constitutional units having pendant cyano groups include —[CH₂CH(C≡N)—] and —[CH₂C(CH₃)(C≡N)—].

Constitutional units having pendant cyano groups can be derived from ethylenically unsaturated monomers such as acrylonitrile or methacrylonitrile, for example, or from a combination thereof. As used herein, the term “(meth)acrylonitrile” indicates that either acrylonitrile or methacrylonitrile, or a combination of acrylonitrile and methacrylonitrile, is suitable for the stated purpose.

In some embodiments, the (D) particulate polymer is a copolymer derived from (meth)acrylonitrile as one co-monomer. However, constitutional units having pendant cyano groups can also be introduced into the polymer by other conventional means. By way of example, the polymer may be a copolymer derived from a cyanoacrylate monomer, such as methyl cyanoacrylate or ethyl cyanoacrylate. In an alternative embodiment, the polymer may be derived from a combination of (meth)acrylonitrile and a cyanoacrylate monomer.

In a particular embodiment of the present invention, the main chain of the polymer can also comprise constitutional units derived from other suitable polymerizable monomers or oligomers. For example, the polymer can comprise constitutional units derived from acrylate esters, methacrylate esters, styrene, hydroxystyrene, acrylic acid, methacrylic acid, methacrylamide, or a combination of any of the foregoing. Especially suitable are constitutional units derived from styrene or methacrylamide. Also suitable are constitutional units derived from methyl methacrylate or allyl methacrylate. In particular, constitutional units having pendant unsubstituted or substituted phenyl groups attached directly to the hydrophobic main chain may be useful. Substituted phenyl groups include, for example, 4-methylphenyl, 3-methylphenyl, 4-methoxyphenyl, 4-cyanophenyl, 4-chlorophenyl, 4-fluorophenyl, 4-acetoxyphenyl, and 3,5-dichlorophenyl. Such constitutional units may be derived from styrene or substituted styrenic monomers, for instance.

In some embodiments, the polymer includes constitutional units having pendant groups that have siloxane functionality. Suitable polymers and the preparation thereof are described in copending and commonly assigned U.S. Ser. No. 10/842,111 that is incorporated by reference herein in its entirety.

In the (D) particulate polymer, a large percentage of the total recurring units can include pendant cyano groups, for example at least 50% and up to and including 95% by mass, and typically at least 60% and up to and including 85% by mass, of the total constitutional units in this polymer can include pendant cyano groups attached directly to the hydrophobic main chain. This polymer can include only a small fraction of constitutional units having two or more pendant groups including two or more poly(alkylene oxide) moieties. Generally at least 0.1% and up to and including 20% by mass, and typically at least 1% and up to and including 10% by mass, of the total constitutional units in this polymer can have two or more pendant groups including two or more poly(alkylene oxide) moieties. When included, a minor fraction of the total constitutional units of this polymer can be derived from other monomers (such as styrene, acrylonitrile, etc.). Generally from 0 to and including 35% by mass, typically at least 1% and up to and including 30% by mass, and more suitably at least 2% and up to and including 25% by mass, of the total constitutional units in this polymer can be derived from other monomers.

In one embodiment, the (D) particulate polymer is a random copolymer consisting essentially of: i) constitutional units having a pendant cyano group attached directly to the hydrophobic main chain; ii) constitutional units having pendant groups including two or more poly(alkylene oxide) moieties; and iii) constitutional units having pendant unsubstituted or substituted phenyl groups attached directly to the hydrophobic main chain.

In another embodiment, the (D) particulate polymer is a random copolymer consisting essentially of: i) constitutional units of the form —[CH₂C(R)(C≡N)—]; ii) constitutional units of the form —[CH₂C(R)(PEO)—], wherein PEO represents two or more pendant groups of the form —C(═O)O—[CH₂CH₂O-]_{y}CH₃, wherein y is in the range from about 25 to about 75; and iii) constitutional units of the form: —[CH₂CH(Ph)-]; wherein each R independently represents —H or —CH₃, and Ph represents a pendant phenyl group.

In yet another embodiment, the (D) particulate polymer is a random copolymer in which about 50 to about 95% by mass of the total constitutional units in the random copolymer are of the form —[CH₂C(R)(C≡N)—]; about 0.1 to about 20% by mass of the total constitutional units in the random copolymer are constitutional units of the two or more forms of —[CH₂C(R)(PEO)—]; and about 2 to about 30% by mass of the total constitutional units in the random copolymer are of the form —[CH₂CH(Ph)-].

Such (D) particulate polymers can be prepared using known processes.

In some embodiments, the (D) particulate polymer can have at least one group selected from the group consisting of a cyano group, an aryl group and an amide group. In this case, the (D) particulate polymer can be at least derived from at least two selected from the group consisting of poly(alkyleneglycol)alkylether(meth)acrylates and poly(alkyleneglycol)(meth)acrylates, and (meth)acrylonitrile, styrene, (meth)acrylamide, or a combination thereof.

By way of example only, the (D) particulate polymers of these embodiments can be formed by polymerization of a combination or mixture of suitable monomers/macromers, such as: A) acrylonitrile, methacrylonitrile, or a combination thereof (i.e., “(meth)acrylonitrile”); B) poly(alkylene glycol)esters of acrylic acid or methacrylic acid, such as poly(ethylene glycol)methyl ether acrylate, poly(ethylene glycol)methyl ether methacrylate, or a combination thereof (i.e., “poly(ethylene glycol)methyl ether(meth)acrylate”); and C) optionally, monomers such as styrene, acrylamide, methacrylamide, or a combination of suitable monomers.

Precursors useful as B) macromers include at least two selected from the group consisting of, for example, polyethylene glycol monomethacrylate, polypropylene glycol methyl ether methacrylate, polyethylene glycol ethyl ether methacrylate, polyethylene glycol butyl ether methacrylate, polypropylene glycol hexyl ether methacrylate, polypropylene glycol octyl ether methacrylate, polyethylene glycol methyl ether acrylate, polyethylene glycol ethyl ether acrylate, polyethylene glycol phenyl ether acrylate, polypropylene glycol monoacrylate, polypropylene glycol monomethacrylate, polypropylene glycol methyl ether methacrylate, polypropylene glycol ethyl ether methacrylate, polypropylene glycol butyl ether methacrylate, (polyethylene glycol/propylene glycol) methylether methacrylate, (polyethyleneglycol/polytetramethyleneglycol) methylether methacrylate, (polyethyleneglycol/polytetramethyleneglycol) methacrylate, poly(vinyl alcohol) monomethacrylate, poly(vinyl alcohol) monoacrylate, and a mixture thereof. Precursors commonly used as a monomer include a combination of at least two selected from the group consisting of poly(ethyleneglycol) methylether methacrylate, poly(ethyleneglycol) monoacrylate, poly(propyleneglycol) methylether methacrylate, (polyethyleneglycol/polytetramethyleneglycol) methacrylate, and poly(propyleneglycol) monomethacrylate. As used herein, the term “(meth)acrylate” with respect to a polymerizable macromer indicates that either an acrylate macromer or a methacrylate macromer, or a combination of acrylate macromers and methacrylate macromers, is suitable for the stated purpose. Also, the phrase “alkyl ether” with respect to a macromer indicates a lower alkyl ether, generally a (C₁-C₆) linear or branched saturated alkyl ether, such as, e.g., a methyl ether or ethyl ether.

Suitable monomers that may be used as optional monomer C) include, for example, acrylic acid, methacrylic acid, acrylate esters, methacrylate esters such as methyl methacrylate, allyl methacrylate, hydroxyethyl methacrylate, styrene, hydroxystyrene, methacrylamide, or a combination of any of the foregoing. Especially suitable monomers are styrene or methacrylamide, or monomers derived therefrom. Specific examples of suitable monomers include styrene, 3-methyl styrene, 4-methyl styrene, 4-methoxy styrene, 4-acetoxy styrene, alpha-methyl styrene, acrylic acid, methyl acrylate, ethyl acrylate, butyl acrylate, n-hexyl acrylate, methacrylic acid, methyl methacrylate, ethyl methacrylate, n-propyl methacrylate, n-butyl methacrylate, n-pentyl methacrylate, neo-pentyl methacrylate, cyclohexyl methacrylate, n-hexyl methacrylate, 2-ethoxyethyl methacrylate, 3-methoxypropyl methacrylate, allyl methacrylate, vinyl acetate, vinyl butyrate, methyl vinyl ketone, butyl vinyl ketone, vinyl fluoride, vinyl chloride, vinyl bromide, maleic anhydride, maleimide, N-phenyl maleimide, N-cyclohexyl maleimide, N-benzyl maleimide, and mixtures thereof.

However, such (D) particulate polymers can be prepared in a hydrophilic medium (water or mixtures of water and alcohol), which may facilitate the formation of particles dispersed in the solvent. Furthermore, it may be desirable to conduct the polymerization in a solvent system that does not completely dissolve the monomer(s) that result in constitutional units that provide hydrophobic character to the polymer main chain or backbone, such as acrylonitrile or methacrylonitrile. By way of example, the (D) particulate polymer can be synthesized in a water/alcohol mixture, such as a mixture of water and n-propanol.

All monomers/macromers and polymerization initiators can be added directly to the reaction medium, with the polymerization reaction proceeding at an appropriate temperature determined by the polymerization initiator chosen. Alternatively, the macromers containing the poly(alkylene oxide) moieties can be added to a reaction solvent first, followed by the slow addition of monomers at an elevated temperature. The polymerization initiator can be added to a monomer mixture, or to a solution of macromer, or both.

Although preparation of the (D) particulate polymer binder has been described in terms of monomers and macromers that can be used to form the co-polymer, practice of the present invention is not limited to the use of copolymers formed by polymerization of a mixture of co-monomers. The polymer can be formed by other routes that will be apparent to those skilled in the art, such as by modification of precursor polymers. In some embodiments, the (D) particulate polymer can be prepared as a graft copolymer, such as where two or more poly(alkyleneoxide) moieties are grafted onto a suitable polymeric precursor. Such grafting can be done, for example, by anionic, cationic, non-ionic, or free radical grafting methods. Other methods of preparation of the graft copolymers suitable for use in the present invention include the methods described in U.S. Pat. No. 6,582,882, the disclosure of which is incorporated herein by reference.

The (D) particulate polymer binder(s) can be present in the imageable layer or the composition for preparing the imageable layer in an amount within the range of at least 10 and up to and including 70% by mass, or at least 20% and up to and including 65% by mass, or more likely at least 30% and up to and including 60% by mass, based on the solid content of the imageable layer or the composition used for preparing the imageable layer.

If the (D) particulate polymer binder is in the form of an aggregate of primary particles, it is possible that the imageable layer according to the present invention can include primary particles with an average particle diameter of less than 300 nm. The primary particle may be present as it is or in the form of aggregates, or both. The polymer particles and the primary particles thereof with an average particle diameter distributed in the range of at least 120 nm and up to and including 400 nm be present in the imageable layer in an amount of at least 20% and up to and including 60% by mass, or at least 25% and up to and including 50% by mass, relative to the solid content of the imageable layer.

Other Optional Components of the Imageable Layer:

Also optionally added to the imageable layer or the composition used for preparing the imageable layer, are co-binder(s) and known additives such as colorants (dyes, pigments), surfactants, plasticizers, stability modifiers, development accelerators, polymerization inhibitors, printing agents, and lubricants (such as silicone powder).

Typical co-binders are water-soluble or water-dispersible polymers, such as, cellulose derivatives such as carboxymethyl cellulose, methylcellulose, hydroxypropyl methylcellulose, hydroxypropyl cellulose, hydroxyethyl cellulose; polyvinyl alcohol; polyacrylic acid; polymethacrylic acid; polyvinyl pyrrolidone; polylactide; polyvinyl phosphonic acid; synthetic co-polymers, such as the copolymer of an alkoxy polyethylene glycol acrylate or methacrylate, for example methoxy polyethylene glycol acrylate or methacrylate, with a monomer such as methyl methacrylate, methyl acrylate, butyl methacrylate, butyl acrylate, or allyl methacrylate; and mixtures thereof. In some embodiments, the co-binder provides crosslinkable sites such as ethylenically unsaturated sites.

Examples of useful dyes include basic oil-soluble dyes such as Crystal Violet, Malachite Green, Victoria Blue, Methylene Blue, Ethyl Violet and Rhodamine B. Examples of commercially available dyes include “Victoria Pure Blue BOH” [manufactured by HODOGAYA CHEMICAL Co., Ltd.], “Oil Blue #603” [Orient Chemical Industries, LTD.], “VPB-Naps (naphthalenesulfonate of Victoria Pure Blue)” [HODOGAYA CHEMICAL Co., Ltd.] and “D 11” [PCAS Co.]; and pigments such as Phthalocyanine Blue, Phthalocyanine Green, Dioxadine Violet and Quinacridone Red.

As for colorants, a color changing agent or a color changing system capable of generating a color change upon exposure can be used. By using this, a distinction between exposed and non-exposed regions on the imageable layer can be more readily observed. Examples of color changing agent or system include (i) triarylmethane-based compounds, (ii) diphenylmethane-based compounds, (iii) xanthene-based compounds, (iv) thiazine-based compounds and (v) spiropyran-based compounds, and specific examples thereof include those described in JP-A-S58-27253. In particular, (i) triarylmethane-based color formers and (iii) xanthene-based color formers are useful because fogging occurs less and high color density is obtained.

Specific examples thereof include Crystal Violet Lactone, Malachite Green Lactone, Benzoyl Leuco Methylene Blue, 3-(N,N-diethylamino)-6-chloro-7-(β-ethoxyethylamino)fluoran, 3-(N,N,N-triethylamino)-6-methyl-7-anilinofluoran, 3-(N,N-diethylamino)-7-chloro-7-o-chlorofluoran, 2-(N-phenyl-N-methylamino)-6-(N-p-tolyl-N-ethyl)aminofluoran, 2-anilino-3-methyl-6-(N-ethyl-p-toluidino)fluoran, 3,6-dimethoxyfluoran, 3-(N,N-diethylamino)-5-methyl-7-(N,N-dibenzylamino)fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino)fluoran, 3-(N,N-diethylamino)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-phthalide, and 3-(4-diethylaminophenyl)-3-(1-ethyl-2-methylindol-3-yl)phthalide. These compounds are used individually or as a mixture.

Examples of surfactants include but are not limited to, fluorine-based surfactants and silicone-based surfactants.

Examples of useful plasticizers include but are not limited to, diethyl phthalate, dibutyl phthalate, dioctyl phthalate, tributyl phosphate, trioctyl phosphate, tricresyl phosphate, tri(2-chloroethyl) phosphate and tributyl citrate.

Useful stabilizers are for example, phosphoric acid, phosphorous acid, oxalic acid, tartaric acid, malic acid, citric acid, dipicolinic acid, polyacrylic acid, benzene sulfonic acid, and toluene sulfonic acid.

Examples of useful stability modifiers include but are not limited to, known phenolic compounds, quinones, N-oxide compounds, amine-based compounds, sulfide group-containing compounds, nitro group-containing compounds and transition metal compounds. Specific examples thereof include hydroquinone, p-methoxyphenol, p-cresol, pyrogallol, t-butylcatechol, benzoquinone, 4,4′-thiobis(3-methyl-6-t-butylphenol), 2,2′-methylenebis(4-methyl-6-t-butylphenol), 2-mercaptobenimidazole, and N-nitrosoenylhydroxyamine primary cerium salts.

Examples of useful development accelerators include but are not limited to, acid anhydrides, phenols, and organic acids. The acid anhydrides can be cyclic anhydrides such as phthalic anhydride, tetrahydrophthalic anhydride, hexahydrophthalic anhydride, 3,6-endoxy-tetrahydrophthalic anhydride, tetrachlorophthalic anhydride, maleic anhydride, chloromaleic anhydride, α-phenyl maleic anhydride, succinic anhydride, and pyromellitic anhydride. Examples of the useful non-cyclic acid anhydrides include acetic anhydride. Examples of phenols include bisphenol A, 2,2′-bishydroxysulfone, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane and 4,4′,3″,4″-tetrahydroxy-3,5,3′,5′-tetramethyltriphenylmethane.

Examples of useful organic acids include but are not limited to, sulfonic acids, sulfonic acids, alkylsulfuric acids, phosphonic acids, phosphate esters and carboxylic acids described in JP-A-S60-88942 and JP-A-H02-96755, and specific examples thereof include p-toluenesulfonic acid, dodecylbenzenesulfonic acid, p-toluenesulfinic acid, ethylsulfuric acid, phenylphosphonic acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 4-dimethylaminobenzoic acid, 4-cyclohexene-1,2-dicarboxylic acid, erucic acid, lauric acid, n-undecanoic acid and ascorbic acid.

Examples of polymerization inhibitors include but are not limited to, hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-tert-butylphenol), 3-mercapto-1,2,4-triazole, and N-nitroso-N-phenylhydroxylamine aluminum salt.

The amount of these various additives can vary depending on the purpose, but is generally up to and including 30% by mass based on the solid content of the imageable layer or the composition used for preparing the imageable layer. In the case of the multi-layer type, the amount of these various additives is up to and including 30% by mass relative to the total solid content of all the imageable layers.

In the imageable layer or the composition used for preparing the imageable layer, alkali-soluble or dispersible resins can be used in combination, if necessary. Examples of the other alkali-soluble or dispersible resins include copolymers of alkali-soluble group-containing monomers such as acrylic acid, methacrylic acid, maleic acid, maleic anhydride, itaconic acid and itaconic anhydride and other monomer(s), polyester resin, and acetal resin.

### Preparation of Imageable Layer

The imageable layer of the negative-working lithographic printing plate precursor according to the present invention can be provided by applying, onto a substrate or an underlayer that can optionally be formed on the substrate, an imageable layer composition containing the above components.

Such imageable layer composition can include at least one solvent. Examples of useful solvents include but are not limited to, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetoamide, N,N-dimethylformamide, tetramethylurea, N-methylpyrrolidone, dimethylsulfoxide, sulfolane, γ-butyrolatone, and toluene. When using a water soluble imageable layer composition, examples of the solvent are aqueous solvents such as water and alcohols. However, the solvent is not limited to these examples, and the solvent can be appropriately selected in accordance with physical properties of the imageable layer. These solvents can be used alone or in the form of a mixture thereof. The concentration of the above-mentioned respective components (all solid contents including the additives) in the solvent is generally at least 1% and up to and including 50% by mass. It should be noted that the particulate polymer binder does not dissolve in the solvent(s).

The application amount (of all the solid contents) onto the substrate after the imageable layer composition is applied and dried varies depending on the use. Regarding a negative-working lithographic printing plate precursor, in general, the applied amount is generally at least 0.5 g/m² and up to and including 5.0 g/m². As the applied amount gets smaller, the apparent sensitivity increases, but the membrane property of the imageable layer gets worse. The imageable layer composition applied onto the substrate is usually dried at elevated temperature. In order to dry within a short time, the negative-working lithographic printing plate precursor can be dried at a temperature of at least 30° C. and up to and including 150° C. for at least 10 seconds and up to and including 10 minutes using a hot-air dryer or an infrared dryer.

The method of the application may be any one selected from various methods, including roll coating, dip coating, air knife coating, gravure coating, gravure offset coating, hopper coating, blade coating, wire doctor coating, and spray coating.

### Other Layers

The negative-working lithographic printing plate precursor of the present invention can appropriately include not only the imageable layer but also other layer(s) such as an underlayer, an overcoat layer, or a backcoat layer in accordance with desired properties.

It is desirable that the overcoat layer be easily removable with a hydrophilic printing liquid, such as a fountain solution, during printing, and comprise one or more resins selected from hydrophilic organic polymer compounds. It is desirable that the hydrophilic organic polymer compound have a film-forming capability, and mention can be made of polyvinylacetate (with a rate of hydrolysis of 65% or more), polyacrylic acid amine salt, polyacrylic acid copolymer, an alkaline metal salt or an amine salt thereof, polymethacrylic acid, an alkaline metal salt or an amine salt thereof, polymethacrylic acid copolymer, an alkaline metal salt or an amine salt thereof, polyacrylamide or a copolymer thereof, polyhydroxyethylacrylate, polyvinylpyrrolidone, a copolymer thereof, polyvinylmethylether, vinylmethylether/maleic anhydride copolymer, poly-2-acrylamide-2-methyl-1-propanesulfonic acid, an alkaline metal salt or an amine salt thereof, poly-2-acrylamide-2-methyl-1-propanesulfonic acid copolymer, an alkaline metal salt or an amine salt thereof, gum Arabic, fibrin derivatives (for example, carboxymethylcellulose, carboxyethylcellulose, and methylcellulose), a modified one thereof, white dextrin, pullulan, enzyme-decomposed etherified dextrin and others known in the art. Depending on the purpose, it can be possible to use two or more of the above resins by mixing them.

It is desirable that the dry amount of the applied overcoat layer be at least 0.1 g/m² and up to and including 2.0 g/m². It is possible within this range to realize blocking of the imageable layer from oxygen, preventing the contamination on the surface of the imageable layer with a lipophilic substance such as a stain caused by fingerprints, or preventing a scratch on the surface of the imageable layer caused by fingernails.

Particularly useful examples of the backcoat layer include those comprising an organic polymer compound described in JP-A-H05-45885 and backcoat layers comprising a metal oxide obtained by hydrolyzing and polycondensating an organic or inorganic metal compound described in JP-A-H06-35174. Among these backcoat layers, particularly useful is a backcoat layer comprising a metal oxide obtained from an alkoxyl compound of silicon, such as Si(OCH₃)₄Si(OC₂H₅)₄, Si(OC₃H₇)₄ or Si(OC₄H₉)₄, which is inexpensive and easily available, and this backcoat is excellent in development resistance.

In the negative-working lithographic printing plate precursor according to the present invention, the imageable layer can be the top layer or outermost layer. However, in some embodiments, an overcoat layer can be present on the imageable layer. As the overcoat layer, an oxygen barrier layer that can prevent or reduce the contact of the imageable layer with oxygen is very useful.

As explained above, it is possible to prepare a negative-working lithographic printing plate precursor according to the present invention.

### Imagewise Exposure

The negative-working lithographic printing plate precursor of the present invention can be imagewise exposed to radiation in accordance with properties of the imageable layer(s) thereof. Specific examples of the method of the exposure include light irradiation, such as irradiation of infrared rays with an infrared laser, irradiation of ultraviolet rays with an ultraviolet lamp, irradiation of visible rays; electron beam irradiation such as γ-ray radiation; and thermal energy application with a thermal head, a heat roll, a heating zone using a non-contact type heater or hot air, or the like. The negative-working lithographic printing plate precursor of the present invention can be used as a so-called computer-to-plate (CTP) plate capable of directly writing images on a plate, using a laser, based on digital image information from a computer. It is also possible to write images by a method using a GLV (Grating Light Valve) or a DMD (Digital Mirror Device) as digital image writing means.

As a light source laser for imagewise exposure of the negative-working lithographic printing plate precursor, a high-output laser having a maximum intensity within the near infrared radiation or the infrared radiation range is useful. Examples of the high-output laser having a maximum intensity within the near infrared radiation or infrared radiation range include various lasers having a maximum intensity within the near infrared radiation or infrared radiation range of at least 760 nm and up to and including 3000 nm, for example, a semiconductor laser and a YAG laser. If necessary, a development treatment can be conducted after writing images on the imageable layer using a laser and heat-treating in a heat oven.

### On-Press Development

The negative-working lithographic printing plate precursor according to the present invention can be transformed into a lithographic printing plate with image(s) by forming image(s) in the imageable layer(s) as latent image(s) with a laser, and subjecting it to a developing process to remove non-imaged (non-exposed) regions from the exposed imageable layer(s).

It is possible to develop the imagewise exposed negative-working lithographic printing plate precursor according to the present invention by mounting it directly on press after imaging or image-wise exposing, and contacting it with either a lithographic printing ink, a fountain solution, or both a lithographic printing ink and a fountain solution during the initial impressions. Thus, the present invention also relates to a process for preparing a lithographic printing plate comprising a step of on-press developing of the negative-working lithographic printing plate precursor.

No separate development step off-press is needed before mounting the exposed precursor onto a press. This eliminates the separate development off-press along with both the processing equipment and developer (processing solution), thus simplifying the lithographic printing process and reducing the amount of expensive equipment required and chemical waste generated. Typical ingredients of aqueous fountain solutions, in addition to water, include pH buffering systems, such as phosphate and citrate buffers; desensitizing agents, such as dextrin, gum arabic, and sodium carboxymethylcellulose; surfactants and wetting agents, such as aryl and alkyl sulfonates, polyethylene oxides, polypropylene oxides, and polyethylene oxide derivatives of alcohols and phenols; humectants, such as glycerin and sorbitol; low boiling solvents such as ethanol and 2-propanol; sequestrants, such as borax, sodium hexametaphosphate, and salts of ethylenediamine tetraacetic acid; biocides, such as isothiazolinone derivatives; and antifoaming agents.

It is useful that the temperature of the fountain solution be kept at a temperature of at least 5° C. and up to and including 90° C., and more likely of at least 10° C. and up to and including 50° C. It is desirable that the time for immersing in the fountain solution be at least 1 second and up to and including 5 minutes. If necessary, slight rubbing of the surface of the plate during development can be carried out.

The negative-working lithographic printing plate precursor according to the present invention can also be subjected to on-press imaging or image-wise exposure as well as on-press development. For on-press imaging, the negative-working lithographic printing plate precursor according to the present invention can be imaged while mounted onto a lithographic printing press cylinder, and the imageable layer is developed on-press afterward using either a fountain solution, a lithographic printing ink, or both a fountain solution and a lithographic printing ink during the initial press operation. This method does not comprise a separate off-press development step and is especially suitable for computer-to-press applications in which the negative-working lithographic printing plate precursor is directly imaged on the plate cylinder according to computer-generated digital imaging information and, with minimum or no treatment, directly prints out regular printed sheets. An example of a direct imaging printing press is the SPEEDMASTER 74-DI press from Heidelberg USA, Inc. (Kennesaw, Ga.).

After on-press developing, printing can then be carried out by successively applying a fountain solution and then lithographic ink to the image on the surface of the printing plate. The fountain solution is taken up and maintained by the non-imaged (non-exposed) regions, that is, the surface of the hydrophilic substrate is revealed by the imaging and development process, and the lithographic printing ink is received in the imaged (exposed) regions, that is, the regions not removed by the on-press development process. The lithographic printing ink is then transferred to a suitable receiving medium (such as cloth, paper, metal, glass or plastic) either directly or indirectly using an offset printing blanket to provide a desired impression of the image thereon.

The negative-working lithographic printing plate precursor according to the present invention can be transformed into a lithographic printing plate not only by on-press developing which is performed on a cylinder of a lithographic printing machine, but also by a developing process using a conventional auto-developing machine and off-press development. The developer (or processing solution) to be used for the developing process using the conventional auto-developing machine can be an alkaline developer having a pH of 10 or more which is common in the art, as well as an acidic or weak-alkaline developer having a pH of less than 10. The developing process can be not only a general developing process composed of a developing step, a rinsing process and a gumming process but also another developing process wherein the developing step and the gumming step are consolidated into one step performed by using only one liquid.

Following development, a postbake treatment can optionally be used to improve lithographic printing plate durability.

As explained above, it is possible for the negative-working lithographic printing plate precursor according to the present invention be imagewise exposed by scanning exposure based on digital signals, and then mounted directly on a printing press machine to perform printing.

The present invention provides at least the following embodiments and combinations thereof, but other combinations of features are considered to be within the scope of the present invention as a skilled artisan would appreciate from the teaching of this disclosure:
1. A negative-working lithographic printing plate precursor, comprising:
   a substrate and a negative-working imageable layer disposed on the substrate,
   wherein:
   the imageable layer is removable by a lithographic printing ink or a fountain solution, or both a lithographic printing ink and a fountain solution, and
   the imageable layer comprises:
   (A) at least one free radical polymerizable compound,
   (B) at least one free radical polymerization initiator, and
   (C) at least one polymer which has a polysaccharide backbone having a radical polymerizable group and that is different from (A).
2. The negative-working lithographic printing plate precursor of embodiment 1 or 2, wherein the polysaccharide in (C) is cellulose or a derivative thereof.
3. The negative-working lithographic printing plate precursor of any of embodiments 1 to 3, wherein the free radical polymerizable group of (C) is bonded to the polysaccharide backbone via either at least one urethane bond or at least one urea bond, or both a urethane bond and a urea bond.
4. The negative-working lithographic printing plate precursor according to any of embodiments 1 to 3, wherein (C) is derived from, at least, a polysaccharide, a polyisocyanate, and either an alcohol other than a polysaccharide or an amine, or both an alcohol other than a polysaccharide or an amine.
5. The negative-working lithographic printing plate precursor of embodiment 4, wherein the alcohol other than a polysaccharide or amine has the free radical polymerizable group.
6. The negative-working lithographic printing plate precursor of any of embodiments 1 to 5, wherein the (C) has at least one poly(alkyleneoxide)moiety.
7. The negative-working lithographic printing plate precursor of any of embodiments 1 to 6, wherein the free radical polymerizable group of (C) is linked to the polysaccharide backbone via a spacer comprising the poly(alkyleneoxide) moiety.
8. The negative-working lithographic printing plate precursor of any of embodiments 1 to 7, wherein (C) is present in the imageable layer in an amount of at least 1% and up to and including 50% by mass, based on the total mass of the imageable layer.
9. The negative-working lithographic printing plate precursor of any of embodiments 1 to 8, wherein (A) has at least one poly(alkyleneoxide) moiety.
10. The negative-working lithographic printing plate precursor of any of embodiments 1 to 9, wherein (A) is a multi-functional urethane acrylate.
11. The negative-working lithographic printing plate precursor of any of embodiments 1 to 10, wherein (B) comprises a heat-polymerization free radical polymerization initiator.
12. The negative-working lithographic printing plate precursor of embodiment 11, wherein the imageable layer further comprises (E) a photothermal conversion material.
13. The negative-working lithographic printing plate precursor of any of embodiments 1 to 12, wherein the imageable layer further comprises (D) at least one particulate polymer binder other than the (C) polymer having a polysaccharide backbone.
14. A method for preparing a lithographic printing plate, comprising:
   on-press developing a negative-working lithographic printing plate precursor of any of embodiments 1 to 13.
15. The method of embodiment 14, comprising:
   imagewise exposing the negative-working lithographic printing plate precursor to provide an imagewise exposed precursor;
   mounting the imagewise exposed precursor onto a printing press; and
   on-press developing the imagewise exposed precursor by contacting it with either a lithographic printing ink, a fountain solution, or both a lithographic printing ink and a fountain solution.
16. The method of embodiment 14, comprising:
   mounting the negative-working lithographic printing plate precursor onto a printing press to provide a mounted precursor;
   imagewise exposing the mounted precursor to provide an imagewise exposed precursor; and
   on-press developing the imagewise exposed precursor by contacting it with either a lithographic printing ink, a fountain solution, or both a lithographic printing ink and fountain solution.

The present invention will be described in more detail by way of examples, which however should not be construed as limiting the scope of the present invention. The “%” hereafter means % by mass (weight).

### Synthesis of Monoisocyanate Compound A:

A solution of DMAAc*¹ (46.4 g), polyethyleneglycol monoacrylate*² (44.83 g), 2,6-di-tert-butyl-methylphenol (0.06 g) and dibutyl tin dilaurate (0.1 g) were charged into a 200 ml four-necked round bottom glass flask (reactor) equipped with a thermometer, a stirrer, and a condenser to which a silica gel packed drying tube was attached. IPDI*³ (18.56 g) which was the same molar amount as the polyethyleneglycol monoacrylate was charged into the reactor, and heated at 60° C. for 14 hours while stirring. Thus, Monoisocyanate Compound A was obtained.

*1) DMAAc: N,N-dimethylacetoacetamide from Tokyo Chemical Industry Co., Ltd., Japan;

*2) Polyethyleneglycol monoacrylate: Blemmer AE-400 (Mw-ca. 500, from NOF Corp., Japan);

*3) IPDI: isophorone diisocyanate from Tokyo Chemical Industry Co., Ltd., Japan.

### Synthesis of Monoisocyanate Compounds B to F:

Monoisocyanate Compounds B to F were obtained in the same manner as in the synthesis of Monoisocyanate Compound A, except that the polyethyleneglycol monoacrylate (hydroxyl group-containing compound: —OH Compound) and IPDI (isocyanate group-containing compound: —NCO compound) were changed as shown in TABLE I.

TABLE I

| Mono- | | | NCO group of —NCO |
|---|---|---|---|
| isocyanate | | | Compound/OH group |
| Com- | —NCO | | of —OH Compound |
| pound | Compound | —OH Compound | (molar ratio) |
| B | TIPTP*⁴ | Sartomer AE-400 | 3/2 |
| C | IPDI | GDMA*⁵ | 2/1 |
| D | IPDI | Sartomer SR399*⁶ | 2/1 |
| E | Toluilene | Blemmer AE-400 | 2/1 |
| | diisocyanate | | |
| F | Toluilene | Sartomer SR399 | 2/1 |
| | diisocyanate | | |

*⁴TIPTP: Desmodur RFE from Bayer Material Science
*⁵GDMA: Glycerol-1,3-dimethacrylate (NK-Ester 701) from Shin-Nakamura Chemical Co., Ltd., Japan
*⁶Sartomer SR399: Dipentaerythritol pentaacrylate from Sartomer Company, Inc., USA

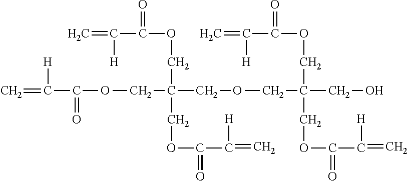 [SMILES: C=CC(=O)OCC(CO)(COCC(COC(=O)C=C)(COC(=O)C=C)COC(=O)C=C)COC(=O)C=C]

### Synthesis of Monoisocyanate Compound G:

DMAAc*(46.4 g) and 3-dimethylaminopropylamine (15.33 g) were charged into a 200 ml four-necked round bottom glass flask (reactor) equipped with a thermometer, a stirrer, and a condenser to which a silica gel packed drying tube was attached, followed by stirring at 30° C. for 30 minutes. IPDI*³ (33.34 g) which had the same molar amount as the 3-dimethylaminopropylamine was charged into the reactor, and heated at 60° C. for 5 hours while stirring. Thus, Monoisocyanate Compound G was obtained.

### Synthesis of Monoisocyanate Compound H:

DMAAc*¹ (46.4 g) and 3-amino-1-propanol (9.01 g) were charged into a 200 ml four-necked round bottom glass flask (reactor) equipped with a thermometer, a stirrer, and a condenser to which a silica gel packed drying tube was attached. Karenz MOI*⁷ (18.62 g) which had the same molar amount as the 3-amino-1-propanol was charged into the reactor for 30 minutes while stirring at 30° C., and further stirred at 30° C. for 4 hours. Then, dibutyl tin dilaurate (0.1 g) and 2,6-di-tert-butyl-4-methylphenol (0.06 g) were added to the reactor. Next, IPDI*³ (26.67 g) which had the same molar amount as the 3-amino-1-propanol was charged into the reactor, and heated at 60° C. for 14 hours. Thus, Monoisocyanate Compound H was obtained.

*7) Karenz MOI: 2-methacryloyloxyethylisocyanate from Showa Denko, Japan

### Synthesis Invention Example 1 Polymer

DMAAc*¹ (600 g) and hydroxypropylcellulose*⁸ (10 g) were charged into a 1000 ml size round bottom glass flask (reactor) equipped with a thermometer, a stirrer, and a condenser to which a silica gel packed drying tube was attached, and heated up to 90° C. while stirring. The hydroxypropylcellulose was dissolved by stirring at 90° C. for 30 minutes. Next, Monoisocyanate Compound A (109.8 g), which has isocyanate groups the molar amount of which was the same as that of the hydroxyl groups of the hydroxypropyl cellulose, was charged into the reactor and heated at 90° C. for 40 hours while stirring. Thus, Polymer 1 was obtained.

*8) Hydroxypropylcellulose: Klucel M (Mw=850,000) from Hercules Incorporated, USA

### Synthesis of Invention Examples 2 to 12 Polymers

Polymers 2-12 were obtained in the same manner as in Synthesis Example 1 except that the polysaccharide compound and the monoisocyanate compound in TABLE II below were used.

TABLE II

| | Polysaccharide | Monoisocyanate | OH group of Polysaccharide |
|---|---|---|---|
| | Compound | Compound | Compound/NCO group of |
| Poly- | (—OH | (—NCO | Monoisocyanate Compound |
| mer | Compound) | Compound) | (molar ratio) |
| 2 | Klucel E*⁹ | A | 6.0/6.0 |
| 3 | Klucel M | B | 6.0/6.0 |
| 4 | HPC SL*¹⁰ | C | 6.0/3.0 |
| 5 | HPC SL | D | 6.0/3.0 |
| 6 | Klucel M | D | 6.0/5.0 |
| 7 | HPC M*¹¹ | A/D | 6.0/4.2/1.8 |
| 8 | Klucel M | E | 6.0/4.8 |
| 9 | HPC L*¹² | E | 6.0/3.0 |
| 10 | HPC SL | F | 6.0/2.0 |
| 11 | Klucel M | D/G | 6.0/3.0/2.0 |
| 12 | Klucel M | A/H | 6.0/2.0/3.0 |

*⁹Hydroxypropylcellulose: Klucel E (Mw = 800,000) from Hercules Incorporated, USA
*¹⁰Hydroxypropylcellulose: Nisso HPC SL (Mw = 10,000) from Nippon Soda Co., Ltd., Japan
*¹¹Hydroxypropylcellulose: Nisso HPC M (Mw = 620,000) from Nippon Soda Co., Ltd., Japan
*¹²Hydroxypropylcellulose: Nisso HPC L (Mw = 140,000) from Nippon Soda Co., Ltd., Japan

### Invention Example 1

### Substrate

The surface of an aluminum sheet was subjected to an electrolytic roughening treatment in a hydrochloric acid bath to obtain a grained aluminum sheet with an average roughness (Ra) of 0.5 μm. Furthermore, the grained aluminum sheet was subjected to an anodizing treatment in an aqueous phosphoric acid solution to form an oxide film at an amount of 2.5 g/m².

Next, a coating solution for an under layer shown in the following TABLE m was applied with a bar coater such that the amount of dried coating was 0.03 g/m², was dried at 120° C. for 40 seconds, and cooled down to 20 to 27° C., to obtain a substrate with the under layer.

TABLE III
Coating Solution for Under Layer

| Component | Amount |
|---|---|
| Polyacrylic acid aqueous solution (40% by mass) | 3.0 g |
| (Jurymer AC-10S marketed by TOAGOSEI | |
| Water | 27.0 g |

Imageable Forming Layer:

On the substrate with the under layer obtained above, a coating solution for an image forming layer shown in the following TABLE IV was coated using a bar coater, followed by drying at 110° C. for 40 seconds, and further cooling to 20 to 27° C. Thus, a negative-working lithographic printing plate precursor was obtained. The amount of the dried coating was 1.0 g/m².

TABLE IV
Coating Solution for Image Forming Layer

| Components | Amount | |
|---|---|---|
| Polymer 1 of Synthesis Example 1 (10% by mass solution) | 2.50 | g |
| PEGMA*¹³/acrylonitrile/styrene terpolymer at 10/70/20 as % by | 6.50 | g |
| weight (24% by mass in solution of 1-propanol/water at 76/24 | | |
| weight % mixture; average particle size of 178 nm) | | |
| Urethanacrylate*¹⁴ | 1.25 | g |
| Sartomer SR399*¹⁵ | 0.75 | g |
| Irgacure 250*¹⁶ | 0.25 | g |
| Infrared absorbing dye of the following Chemical Formula 1 | 0.15 | g |
| 3-Mercapto-1,2,4-triazole*¹⁷ | 0.05 | g |
| BYK336*¹⁸ | 0.16 | g |
| 1-Propanol | 38.92 | g |
| Methyl ethyl ketone | 40.15 | g |
| γ-butyrolactone | 0.92 | g |
| Water | 8.40 | g |

*¹³Polyethyleneglycol methylether methacrylate from Sigma Aldrich
*¹⁴2-Butanone solution with a concentration of 80% by mass of a polymerizable compound obtained by reacting DESMODUR ® N100 (aliphatic polyisocyanate resin including hexamethylene diacrylates marketed by Bayer) with hydroxyethylacrylate and pentaerythritoltriacrylate
*¹⁵Trimethylolpropanetetraacrylate (marketed by Sartomer Company)
*¹⁶Propylenecarbonate solution with a concentration of 75% by mass of iodonium (4-methoxyphenyl[4-(2-methylpropyl)phenyl]hexafluorophosphate (marketed by Chiba Specialty Chemicals)
*¹⁷3-Mercapto-1,2,4-triazole available from PCAS (France)
*¹⁸Xylene/methoxypropyl acetate solution with a concentration of 25% by mass of a modified dimethylpolysiloxane copolymer from BYK Chemie
Chemical Formula 1:

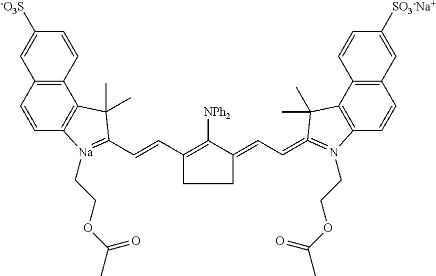

### Invention Examples 2 to 12

Negative-working lithographic printing plate precursors were obtained in the same manner as in Invention Example 1, except that Polymers 2-12 obtained in Synthesis of Examples 2-12 were used in place of Polymer 1 obtained in Synthesis Example 1.

### Comparative Example 1

A negative-working lithographic printing plate precursor was obtained in the same manner as in Invention Example 1, except that Klucel E was used in place of Polymer 1 obtained in Synthesis Example 1.

### Comparative Example 2

A negative-working lithographic printing plate precursor was obtained in the same manner as in Invention Example 1, except that Sartomer SR399 was used in place of Polymer 1 obtained in Synthesis Example 1.

### Comparative Example 3

A negative-working lithographic printing plate precursor was obtained in the same manner as in Invention Example 1, except that Polymer 1 obtained in Synthesis Example 1 was not used.

### Evaluations

### Exposure

Each of the negative-working lithographic printing plate precursors of Invention Examples 1-12 and Comparative Examples 1-3 was image-wise exposed at a rate of 150 mJ/cm², using Magnus 800 (Kodak) image setter with a laser which can emit a IR rays with a power of 23 W and a wavelength of 830 nm.

On-Press Developability and Initial Ink Receptivity:

Each of the exposed negative-working lithographic printing plate precursors was mounted on a printing press machine (MAN Roland R-201) without being developed. A fountain solution (Presarto WS100 marketed by DIC Graphics)/isopropylalcohol/water=1/1/98 (volume ratio)) and printing ink (Fusion G Red N marketed by DIC Graphics) were supplied, and printing was performed at a printing rate of 6,000 sheets/hour. The on-press developability was evaluated by the number of printed paper sheets when ink did not transfer to unexposed regions (non-image regions) on the imageable layer. The initial ink receptivity was evaluated by the number of printed paper sheets when the ink concentration of image regions on the printed paper reached the necessary concentration by the transfer of ink to the exposed regions (image regions).

On-Press Development Stability Over Time:

Each of the negative-working lithographic printing plate precursors was stored (aged) 14 days at 40° C. under 80% relative humidity conditions. After storage, the aged negative-working lithographic printing plate precursors were exposed as above, and the thus-obtained plates were then mounted on a printing press machine (MAN Roland R-201) to evaluate the on-press developability after storage in the same manner as mentioned above.

Printing Press Life:

Each of the negative-working lithographic printing plate precursors was exposed as above, and the exposed ones were mounted on a Lithrone S-26 press machine (Komori). A fountain solution (Presarto WS100 marketed by DIC Graphics)/isopropylalcohol/water=1/1/98 (volume ratio)) and printing ink (Fusion G Red N marketed by DIC Graphics) were supplied, and printing was performed at a printing rate of 6,000 sheets/hour. When the number of printed paper sheets increased by continued printing, the imageable layer of the lithographic printing plate was gradually worn away, and the ink receptivity thereof deteriorated. Thus, the ink concentration on the printed paper sheets was reduced. The printing press life was evaluated by the number of printed paper sheets when the ink concentration (reflective concentration) thereon was reduced to 90% or less of that when the printing started.

The evaluation results of on-press developability, on-press development stability, initial ink receptivity and printing press life are shown in TABLE V.

TABLE V

| | | | | On-Press | |
|---|---|---|---|---|---|
| | | Initial | | Develop- | Printing |
| | | Ink | On-Press | ability | Press |
| | | Recep- | Develop- | After | Life*²¹ |
| | | tivity*¹⁹ | ability*²⁰ | Storage*²⁰ | (×10000 |
| Example | Polymer | (sheets) | (sheets) | (sheets) | sheets) |
| Invention 1 | 1 | 8 | 2 | 7 | 14 |
| Invention 2 | 2 | 8 | 2 | 8 | 13 |
| Invention 3 | 3 | 8 | 2 | 7 | 15 |
| Invention 4 | 4 | 7 | 3 | 8 | 14 |
| Invention 5 | 5 | 7 | 3 | 9 | 15 |
| Invention 6 | 6 | 7 | 3 | 9 | 16 |
| Invention 7 | 7 | 8 | 3 | 8 | 14 |
| Invention 8 | 8 | 8 | 2 | 8 | 14 |
| Invention 9 | 9 | 8 | 2 | 8 | 15 |
| Invention 10 | 10 | 7 | 3 | 10 | 16 |
| Invention 11 | 11 | 7 | 3 | 10 | 17 |
| Invention 12 | 12 | 7 | 3 | 9 | 16 |
| Comparative 1 | Klucel E | 25 | 5 | 15 | 7 |
| Comparative 2 | Sartomer | 15 | 10 | 70 | 8 |
| | SR399 | | | | |
| Comparative 3 | None | 20 | 15 | 100 | 7 |

*¹⁹Initial ink receptivity: the fewer, the better
*²⁰On-press developability and on-press developability over time: the fewer, the better
*²¹Printing press life: the more, the better

As is apparent from TABLE V, the negative-working lithographic printing plate precursors of Invention Examples 1 to 12 exhibited better on-press developability, on-press development stability over time, ink receptivity and printing press life, as compared with the negative-working lithographic printing plate precursors of Comparative Examples 1 to 3.

The invention has been described in detail with particular reference to certain preferred embodiments thereof, but it will be understood that variations and modifications can be effected within the spirit and scope of the invention.

1. A negative-working lithographic printing plate precursor, comprising:
a substrate and a negative-working imageable layer disposed on the substrate,
wherein:
the imageable layer is removable by a lithographic printing ink or a fountain solution, or both a lithographic printing ink and a fountain solution, and the imageable layer comprises:
(A) at least one free radical polymerizable compound,
(B) at least one free radical polymerization initiator, and
(C) at least one polymer which has a polysaccharide backbone and a radical polymerizable group that is connected to the polysaccharide backbone via a linkage comprising two urea bonds, two urethane bonds, or a urea bond and a urethane bond, and the polymer is different from (A).

2. The negative-working lithographic printing plate precursor of claim 1, wherein the polysaccharide in (C) is cellulose or a derivative thereof.

3. The negative-working lithographic printing plate precursor of claim 1, wherein the free radical polymerizable group of (C) is bonded to the polysaccharide backbone via either two urethane bonds or two urea bonds.

4. The negative-working lithographic printing plate precursor according to claim 1, wherein (C) is derived from, at least, a polysaccharide, a polyisocyanate, and either an alcohol other than a polysaccharide or an amine, or both an alcohol other than a polysaccharide or an amine.

5. The negative-working lithographic printing plate precursor of claim 4, wherein the alcohol other than a polysaccharide or amine has the free radical polymerizable group.

6. The negative-working lithographic printing plate precursor of claim 1, wherein (C) has at least one poly(alkyleneoxide)moiety.

7. The negative-working lithographic printing plate precursor of claim 1, wherein the free radical polymerizable group of (C) is linked to the polysaccharide backbone via a spacer comprising the poly(alkyleneoxide) moiety.

8. The negative-working lithographic printing plate precursor of claim 1, wherein (C) is present in the imageable layer in an amount of at least 1% and up to and including 50% by mass, based on the total mass of the imageable layer.

9. The negative-working lithographic printing plate precursor of claim 1, wherein (A) has at least one poly(alkyleneoxide) moiety.

10. The negative-working lithographic printing plate precursor of claim 1, wherein (A) is a multi-functional urethane acrylate.

11. The negative-working lithographic printing plate precursor of claim 1, wherein (B) comprises a heat-polymerization free radical polymerization initiator.

12. The negative-working lithographic printing plate precursor of claim 11, wherein the imageable layer further comprises (E) a photothermal conversion material.

13. The negative-working lithographic printing plate precursor of claim 1, wherein the imageable layer further comprises (D) at least one particulate polymer binder other than (C).

14. A method for preparing a lithographic printing plate, comprising:
on-press developing a negative-working lithographic printing plate precursor of claim 1.

15. The method of claim 14, comprising:
imagewise exposing the negative-working lithographic printing plate precursor to provide an imagewise exposed precursor;
mounting the imagewise exposed precursor onto a printing press; and
on-press developing the imagewise exposed precursor by contacting it with either a lithographic printing ink, a fountain solution, or both a lithographic printing ink and a fountain solution.

16. The method of claim 14, comprising:
mounting the negative-working lithographic printing plate precursor onto a printing press to provide a mounted precursor;
imagewise exposing the mounted precursor to provide an imagewise exposed precursor; and
on-press developing the imagewise exposed precursor by contacting it with either a lithographic printing ink, a fountain solution, or both a lithographic printing ink and fountain solution.
